(19) United States
(12) Patent Application Publication
(10) Pub. No.: US 2022/0069546 A1
(43) Pub. Date: Mar. 3, 2022

(54) CONTROL OF VCSEL SPATIAL MODES AND OUTPUT BEAM

(71) Applicant: Array Photonics, Inc., Tempe, AZ (US)

(72) Inventors: Radek ROUCKA, East Palo Alto, CA (US); Philip DOWD, Gilbert, AZ (US); Sabeur SIALA, Sunnyvale, CA (US)

(73) Assignee: Array Photonics, Inc., Tempe, AZ (US)

(21) Appl. No.: 17/423,459

(22) PCT Filed: Jan. 8, 2020
(86) PCT No.: PCT/US2020/012771

§ 371 Date: Jul. 15, 2021

Related U.S. Application Data
(60) Provisional application No. 62/793,557, filed on Jan. 17, 2019.

(51) Int. Cl. H01S 5/183

(52) U.S. Cl. CPC H01S 5/18327; H01S 5/18311; H01S 5/18388; H01S 5/1833

(57) ABSTRACT

A VCSEL device having non-coaxial-with-one-another apertures and/or rotationally asymmetric apertures formed in layer(s) of the VCSEL structure to define more than one spatial mode in a light output in operation of the device. An array of such VCSEL devices configured to have different spatial modes at the output of different constituent VCSEL devices. Spatial asymmetry of structure of the constituent VCSEL devices and, therefore, arrays of VCSEL devices causes the overall light output to form an irregular grid of output spots of light. When the VCSEL array is equipped with an appropriate lens array, the spatial components of the light output of the VCSEL array are caused to overlap in the far at the imaging plane in a multiple spatial (and spectral) mode fashion, thereby reducing speckle in imaging applications.

### CROSS-REFERENCE TO RELATED APPLICATIONS

This international application claims priority from and benefit of the U.S. Provisional Patent Application No. 62/793,557 filed on Jan. 17, 2019, the disclosure of which is incorporated by reference herein in its entirety.

### TECHNICAL FIELD

The present invention relates to vertical-cavity semiconductor lasers (VCSELs), and arrays of VCSELs. More particularly, this disclosure relates to VCSELs and VCSEL arrays having controlled distribution of spatial (also referred to as transverse) modes. VCSELs employing structural features configured to control output light distribution can have improved performance in applications including illumination, sensing and communications.

### RELATED ART

Vertical-cavity surface-emitting lasers (VCSELs) are a class of semiconductor lasers with many applications and offer various advantages when compared to edge-emitting lasers. The planar structure of these devices, configured to provide light emission along an axis that is transverse to the layers of the semiconductor structure, allows on-wafer testing (before dicing and packaging of individual devices or arrays); the ability to form both one-dimensional and two-dimensional arrays; low divergence output beams that facilitate efficient coupling to optical fibers, waveguides and other optical elements; the use of traditional low-cost light emitting diode (LED) packaging technology; as well as integration with electronic, optoelectronic and optical elements, high reliability and high efficiency.

The successful use of VCSELs and VCSEL arrays has been demonstrated in optical-fiber-based data and telecommunication applications (typically over shorter distances of about 1 mile or less, such as in local area networks and data centers, for example), but they are now finding use in a variety of other applications including free-space optical interconnects, sensors, illumination sources for systems such as three-dimensional cameras or gesture recognition systems, dot projectors for structured-light sources, and automotive LIDAR. These devices typically operate at wavelengths of about 850 nm (which light is produced using gallium arsenide (GaAs) quantum-well (QW) active regions), wavelength(s) between about 940 nm and 980 nm (when indium gallium arsenide (InGaAs) QW active regions are employed), and—more recently—wavelength(s) between about 1250 nm and 1600 nm (when devices are structured to utilize dilute nitride QW active regions).

For some applications, such as data communications or sensing, it is generally desirable to provide a VCSEL device characterized by a substantially single-mode operation with an output beam having a substantially circular cross-section. Output power of such single mode operation can be limited, however, and special control is required to enhance the available single-mode-power output. Other applications (such as 3D imaging, illumination, object or gesture recognition, LIDAR, optical coherence tomography, and interference microscopy, for example) can also benefit from an improved mode control, where the output beam has a differently-shaped cross-sectional distribution of irradiance, such as one with a ring shape, or a dumb-bell shape, or where multiple transverse modes exist. Since such applications require higher levels of optical power (ranging from a few tens of milliwatts up to about 10 W), the use of laser arrays instead of single laser device may be preferred. To ensure the devices perform with the desired characteristics, mode-controlling techniques are usually applied to the VCSEL device.

Improvement of single-mode emission in VCSELs was achieved through control of at least one of the spatial distribution of reflectivity and optical loss. (For example, the use of a passive anti-guide region was demonstrated to yield an improved single-mode performance.) Another approach was to spatially modify either the reflective feedback from at least one of the mirrors that are included in the VCSEL structure, or the optical loss for different modes having different spatial distributions. A limitation of both of these techniques, however, is that the maximum achievable single-(spatial)-mode output power is relatively low.

In the case of ring-mode devices, the industrial standards require either the appropriate patterning of the laser reflectors (which can expose aluminum-containing layers, thereby affecting reliability of operation of the laser structure and, quite possibly, current injection) or a complex and involved formation of multiple apertures.

A person of skill readily appreciates that there remains a need to control the spatial mode performance of VCSEL devices, to ensure multimode operation or ring-mode operation. Furthermore, in applications such as imaging or illumination, the spatial output patterns from the devices should overlap in the far-field in order to reduce speckle contrast, which arises from the coherence of laser sources. When coherent light is reflected from a diffused surface, it is as though each point of the surface is emitting a light wave. Generally, all of the reflected light waves have the same frequency, but the phase and amplitude of the light reflected from different parts of the surface will vary. The light will interfere constructively and destructively producing a pattern of light and dark spots that appears random. In an array of VCSELs, while an individual device can be coherent, the individual VCSELs in a laser array are not coherent with each other, and if the emission from the VCSELs overlaps, for example, in the far-field, the speckle contrast for an array decreases as the square root of the number of devices in an array.

Similarly, the speckle contrast is a function of the speckle contrast of an individual laser, and the individual VCSEL speckle contrast can be reduced in devices operating with multiple spatial output spots, filaments and transverse modes. While an individual spatial filament or mode within a device aperture can be fully coherent, the degree of coherence of the superposition of all transverse modes or filaments within a device aperture is reduced, which reduces the speckle contrast produced by a device. The different spatial modes or filaments can also exhibit different wavelengths and thus the linewidth of a multimode VCSEL can be greater than 0.5 nm or 1 nm or 1.5 nm.

### SUMMARY

Embodiments of the invention provide a vertical cavity surface-emitting laser (VCSEL) structure that includes first and second reflectors; a gain medium between these reflectors; a peripheral material layer having an output aperture in this layer; and at least one confining material layer disposed across the longitudinal axis of the VCSEL structure between the first and second reflectors. Such confining material layer has at least one confining aperture in it. (In a specific case, at least one of the output aperture and the at least one confining aperture may be dimensioned to be between 3 microns and 50 microns.) In addition, the first and second axes (the first being an axis of the output aperture and transverse to a plane of the output aperture, and the second being an axis of the at least one confining aperture and transverse to a plane of at least one confining aperture) do not coincide with one another. In one implementation, the VCSEL structure is configured to satisfy at least one of the following conditions: a) the output aperture is dimensioned to have no more than two axes of symmetry in the plane of the output aperture; a lateral extent (of at least one of the peripheral material layer and at least one confining material layer) considered in a first plane that is transverse to the longitudinal axis is smaller than a lateral extent of the active region in a second plane that is parallel to the first plane; and c) at least one confining layer includes first and second confining layers each of which is disposed between the first and second reflectors, while the first and second confining layers are located on the opposite sides of the gain medium. Alternatively or in addition, the VCSEL structure may have only one axis of symmetry. In substantially any implementation, at least one of the following conditions may be satisfied: i) a value of a lateral offset (measured in a plane parallel to a plane of at least one confining aperture) between the first axis and the second axis is at least 1 micron; and ii) such value of the lateral offset does not exceed 40% of a dimension of the at least one confining aperture at hand. Alternatively or in addition, the peripheral material layer may be configured as a metallic layer providing an electrical contact layer of the VCSEL structure, and/or be dimensioned to include a first peripheral portion and a second portion surrounded by the first peripheral portion. (In such a case, the first peripheral portion may be dimensioned to define a ring-shaped stripe of material while the second portion may be dimensioned to satisfy one of the following conditions: (i) the second portion is configured as radially-extended stripe of material, and (ii) the second portion is configured as a stripe connecting two different sides of a polygonally-shaped first peripheral portion and while the first and second portion is electrically connected at at least one point. Alternatively, in substantially any implementation where the peripheral material layer is dimensioned to include a first peripheral portion and a second portion surrounded by the first peripheral portion, the first peripheral portion may be dimensioned to define a closed upon itself stripe of material having a closed internal perimeter and a closed external perimeter, and the second portion may be dimensioned to cover a geometrical center of the first peripheral portion.)

In some cases, the implementation of the VCSEL structure of the invention may be configured to generate a light output that provides, in operation, a spatial distribution of irradiance in one of the following forms: a) a ring-shaped distribution of irradiance, and b) a dumb-bell-shaped distribution of irradiance (as defined in a plane transverse to an axis of the light output) and/or to satisfy at least one of the following conditions: i) at least one confining layer present in the structure includes first and second confining layers (the first confining layer having a first confining aperture therein and the second confining layer having a second confining aperture therein); and ii) these first and second confining layers are located on the opposite sides of the gain medium. (Alternatively or in addition, the VCSEL structure may be configured to satisfy at least one of the following conditions: a) a first portion of at least one of these first and second confining layers has a density of oxygen molecules that is lower than that of a second portion of the at least one of the first and second confining layers, and b) a first portion of at least one of the first and second confining layers has electrical resistivity that is lower than that of a second portion of the at least one of the first and second confining layers. Here, the first portion defines a chosen confining aperture, of the first and second confining apertures, and the second portion is located outside of this chosen confining aperture of the first and second confining apertures. Alternatively or in addition, the first and second confining apertures may be formed such that an axis of the first confining aperture and an axis of the second confining aperture may not coincide with one another—in which case there exists a non-zero lateral offset between projections of a center of the first confining aperture and a center of the second confining aperture on a plane that is substantially parallel to a plane of the at least one confining material layer.) In substantially any implementation, at least one of the first and second reflectors of the VCSEL structure may be configured as a distributed Bragg reflector (DBR), and in this case at least one of the first and second confining layers may be disposed within bounds of the DBR.

Embodiments of the invention additionally provide a VCSEL array that includes a plurality of the VCSEL structures each configured according to an implementation described above. In one case, such VCSEL array is structured to satisfy at least one of the following conditions: a) a first VCSEL structure from the plurality is different from a second VCSEL structure from the plurality of the VCSEL structures; b) at least two output apertures (respectively-corresponding to two VCSELs structures of the plurality of the VCSEL structures) have no more than two axes of symmetry each, while an axis of symmetry in this case is defined in a plane of a corresponding aperture; c) each of at least first and second VCSEL structures from the plurality of the VCSEL structures has corresponding output and confining apertures that are not co-axial with one another, and d) a VCSEL structure from the plurality of the VCSEL structures has an output aperture that is rotationally-symmetric, while a confining aperture of such VCSEL structure is not co-axial with the output aperture of this VCSEL structure (from the plurality of the VCSEL structures of the array).

Alternatively or in addition, the implementation of the VCSEL array may include a plurality of lens elements respectively-corresponding to and operably cooperated with the plurality of the constituent VCSEL structures. In this case, i) first and second locations, defined within bounds of the first and second output apertures of respectively-corresponding first and second VCSEL structures, and ii) first and second axes of respectively-corresponding first and second lens elements from the plurality of lens elements may be made shifted with respect to one another in a plane parallel to a layer of a VCSEL structure from the plurality of the VCSEL structures. Alternatively or in addition, at least one of the following conditions may be satisfied: a) longitudinal axes of constituent VCSEL structures of the array form a first spatially-irregular grid of axes, and b) optical axes of lens elements from the plurality of lens elements form a second spatially-irregular grid of axes. Optionally, the plurality of lens elements may be formed on the same substrate and configured as a stand-alone optical component (in which case such plurality of lens elements may be placed, if desired, to be separated from the plurality of the VCSEL structures by this same substrate).

Embodiments of the invention additionally provide a vertical cavity surface-emitting laser (VCSEL) structure that has a longitudinal axis and that includes first and second reflectors; a gain medium between the first and second reflectors; and a peripheral material layer defining an output aperture therein, the output aperture dimensioned to have no more than two axes of symmetry of the output aperture. This structure may additionally contain at least one confining material layer disposed across the longitudinal axis between the first and second reflectors (the confining material layer defining at least one confining aperture in this layer). Here, an axis of the output aperture and an axis of the at least one confining aperture may be made to not coincide with one another.

Substantially in any embodiment, the VCSEL structure of the invention may be configured such that at least one of i) the at least one confining aperture and ii) the output aperture is substantially coaxial with the longitudinal axis of the structure itself; and/or such that a lateral extent of at least one of the peripheral material layer and the at least one confining material layer in a first plane is smaller than a lateral extent of the active regions in a second plane (here, the first plane is defined to be transverse to the longitudinal axis, and the second plane is defined to be parallel to the first plane); and/or such that at least one confining layer present in the structure includes first and second confining layers (each of which is disposed between the first and second reflectors) while the first and second confining layers are located on the opposite sides of the gain medium; and/or such that the VCSEL structure has only one axis of symmetry.

Alternatively or in addition, and in substantially any implementation of the VCSEL structure, the peripheral material layer may be configured as a metallic layer structured as an electrical contact layer of the VCSEL structure, and/or the peripheral material layer may be dimensioned to include a first peripheral portion and a second portion surrounded by the first peripheral portion. (Or, in the alternative, the first peripheral portion may be dimensioned to define a closed upon itself stripe of material having a closed internal perimeter and a closed external perimeter, while the second portion is dimensioned to cover a center of the first peripheral portion. In one specific case, the first peripheral portion may be dimensioned to define a ring-shaped stripe of material and the second portion may be dimensioned to satisfy one of the following conditions: (i) the second portion is configured as radially-extended stripe of material, and (ii) the second portion is configured as a stripe connecting two different sides of a polygonally-shaped first peripheral portion; at the same time, the first and second portions are made electrically connected with one another at at least one point. Furthermore, the first peripheral portion may be dimensioned to define a stripe of material having a closed polygonal perimeter, while the second portion is dimensioned such as to cover a surface area enclosed by the first peripheral portion and to establish electrical contact with at least one side of the polygonal perimeter.)

In substantially any implementation, the VCSEL structure may be configured to generate, in operation, a light output that includes multiple spatial modes; and/or to generate such light output in which a spatial distribution of the light output is not symmetric with respect to the axis of the output aperture; and/or have the output aperture dimensioned to be is between about 3 microns and about 50 microns; and/or to generate light having a spectral bandwidth (or spectral linewidth) of a width that satisfies at least one of the following conditions i) this width is greater than 0.5 nm; b) this width is greater than 1.0 nm; and c) this width greater than 1.5 nm; and/or to generate a light output that has a spatial distribution of irradiance in a form of a ring, as defined in a plane transverse to an axis of the light output (or, alternatively, a spatial distribution of irradiance that has a dumb-bell shape, as defined in the same plane).

In at least one embodiment, a first aperture (chosen from the output aperture and the at least one confining aperture), has a first dimension while a second aperture (from the remaining apertures) has a second dimension, such that a difference between the first and second dimensions satisfies at least one of the following conditions: a) such difference is equal to or smaller than 6 microns; b) such difference is equal to or smaller than 4 microns; and c) such difference is equal to or smaller than 2 microns. In at least one embodiment, the first and second apertures can be formed such that a first axis of the first aperture and a second axis of the second aperture are made substantially parallel to one another and separated by a distance that satisfies at least one of the following conditions: a) such distance is smaller than 40% of a value representing a dimension of the smallest of the first and second apertures; and b) such distance is at least 1 μm. Optionally, the first and second apertures can be formatted to have substantially equal dimensions.

In at least one embodiment—and preferably in any embodiment—the peripheral material layer may be a layer of metal, while the at least one confining material layer is configured to spatially-confine a spatial distribution of current, during the operation of the VCSEL structure, within the at least one confining aperture. In a specific case, there may be first and second confining material layers in the VCSEL structure (the first confining material layer having a first confining aperture and the second confining material layer having a second confining aperture). In this case, the VCSEL structure may be configured to satisfy at least one of the following conditions: a) a first portion of at least one of the first and second confining material layers has a lower density of oxygen molecules than a second portion of the at least one of the first and second confining layers, and b) a first portion of at least one of the first and second confining layers has electrical resistivity that is lower than that of a second portion of the at least one of the first and second confining material layers (while the first portion defines a chosen confining aperture of the first and second confining apertures and the second portion is located outside of such chosen confining aperture).

In substantially any implementation containing first and second confining material layers, at least one of the first and second reflectors may be configured as a distributed Bragg reflector (DBR), and/or at least one of the first and second confining material layers may be disposed within the bounds of the DBR, and/or the first and second confining material layers may be disposed on the opposite sides of the gain medium.

In substantially any implementation, multiple embodiments of the above-described VCSEL structures can be judiciously grouped to form a VCSEL array. Such VCSEL array can be configured to satisfy at least one of the following conditions: a) a first VCSEL structure from the plurality of the constituent VCSEL structures is different from a second VCSEL structure from such plurality; b) at least two output apertures, respectively-corresponding to two VCSELs structures from the plurality, have no more than two axes of symmetry each (here, an axis of symmetry defined in a plane of a corresponding aperture); and c) each of at least first and second VCSEL structures from the plurality has corresponding output and confining apertures that are not co-axial with one another. In at least one embodiment of the array, the array may additionally contain a plurality of lens elements respectively-corresponding to and operably cooperated with the plurality of the constituent VCSEL structures. Here, i) first and second locations, defined within the bounds of the first and second output apertures of respectively-corresponding first and second constituent VCSEL structures of the array, and ii) first and second axes of respectively-corresponding first and second lens elements from the plurality of lens elements can be structured to be spatially shifted—with respect to one another—in a plane parallel to a layer of a VCSEL structure of the array. Alternatively or in addition, in such a VCSEL array at least one of the following conditions may be satisfied: a) longitudinal axes of constituent VCSEL structures form a first spatially-irregular grid of axes, and b) optical axes of lens elements from the plurality of lens elements form a second spatially-irregular grid of axes; and/or the plurality of lens elements is formed on the same substrate to define a stand-alone optical component; and/or such plurality of lens elements is disposed to be separated from the plurality of the VCSEL structures by the very same substrate.

### BRIEF DESCRIPTION OF THE DRAWINGS

The following Description is made in reference to the Drawings that are used for illustration of but examples of implementations of the idea of the invention, are generally not to scale, and are not intended to limit the scope of the present disclosure. Of the Drawings:

FIGS. 1A, 1B show cross-sections of some VCSEL structures.

FIG. 2 illustrates cross-sections of VCSEL structures possessing mode control.

FIG. 3 represents a schematic cross section for a VCSEL having a metal output aperture offset from a single confining aperture.

FIG. 4 shows a schematic cross section for a VCSEL having a metal output aperture offset from a single confining aperture.

FIG. 5 depicts schematically a cross section for a VCSEL having a metal output aperture and two confining apertures, where the apertures are laterally offset with respect to each other.

FIG. 6 shows a top view of an array of VCSEL devices with a systematic aperture offset change across the array.

FIG. 7 shows a top view of an array of VCSEL devices with random aperture offsets across the array.

FIG. 8 is a top view of a segmented VCSEL array.

FIGS. 9A, 9B, 9C, 9D, 9E, 9F provide top views of metal-defined output apertures of VCSELs according to embodiments of the invention.

FIG. 10 is a top view of an array of VCSEL output apertures having different output aperture shapes.

FIG. 11A illustrates a schematic cross section of a VCSEL array integrated with a microlens array.

FIG. 11B shows a schematic cross section of a VCSEL array integrated with a microlens array.

FIG. 12 shows a schematic cross section of a VCSEL array integrated with a microlens array.

FIGS. 13A, 13B, 13C illustrate schematically the spatial mode pattern and transverse current and light distribution for VCSEL output apertures having different spatial offsets.

FIGS. 14A, 14B, 14C show schematically the transverse current and light distribution at higher current injection levels for VCSEL output apertures having spatially different offsets.

FIGS. 15A, 15B, 15C depict schematically the transverse current and light distribution at still higher current injection levels for VCSEL output apertures having differing spatial offsets, where a transverse mode hop has occurred.

Generally, to facilitate clarity of presentation, not all elements present in one Drawing may necessarily be shown in another.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. Various embodiments discussed below are not necessarily mutually exclusive, and sometimes can be appropriately combined. The following detailed description is, therefore, not to be taken in a limiting sense, and the scope of the embodiments of the present invention is defined only by the appended claims, along with the full scope of equivalents to which such claims are entitled.

Notwithstanding that the numerical ranges and parameters used in the description are approximations, these numerical values in the specific examples are reported as precisely as possible. Any numerical value, however, inherently contains certain errors necessarily resulting from the standard variation found in their respective testing measurements.

In particular, any numerical range recited herein is intended to include all sub-ranges encompassed therein and are inclusive of the range limits. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

Also, in this application, the use of “or” means “and/or” unless specifically stated otherwise, even though “and/or” may be explicitly used in certain instances.

The term “lattice-matched”, or similar terms, refer to semiconductor layers for which the in-plane lattice constants of the materials forming the adjoining layers materials (considered in their fully relaxed states) differ by less than 0.6% when the layers are present in thicknesses greater than 100 nm. Further, in devices such as VCSELs with multiple layers forming individual regions (such as mirrors) that are substantially lattice-matched to each other means define the situation when all materials in the junctions, that are present in thicknesses greater than 100 nm and considered in their fully-relaxed stated, have in-plane lattice constants that differ by less than 0.6%. Alternatively, the term substantially lattice-matched or “pseduomorphically strained” may refer to the presence of strain within a layer (which may also be thinner than 100 nm), as would be understood from context of the discussion. As such, base material layers, of a given layered structure, can have strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Layers made of different materials with a lattice parameter difference, such as a pseudomorphically strained layers, can be grown on top of other lattice matched or strained layers without generating misfit dislocations. The term “strain” generally refers to compressive strain and/or to tensile strain.

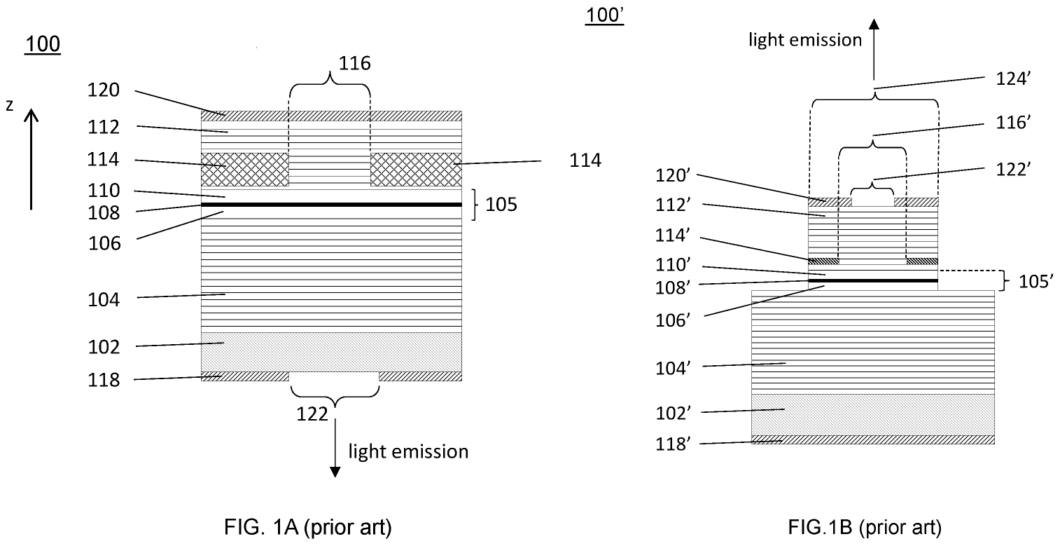

In reference to structured mentioned above, schematic cross-sectional views of two typical VCSEL devices are shown in FIGS. 1A and 1B. FIG. 1A illustrates the cross-section of a gain-guided VCSEL structure 100, formed using ion implantation, and FIG. 1B shows the cross-section of a VCSEL structure 100′ possessing an oxide-defined aperture. The devices 100, 100′ include general structural elements common to many VCSELs, including embodiments of VCSELs and VCSEL arrays described below. VCSELs typically include first and second minors or reflectors, such as Distributed Bragg Reflectors (hereinafter referred to as “DBRs”), formed on opposite sides of an active region. A given VCSEL can be driven or pumped electrically (for example, by forcing current through the active region) or optically (by supplying or pumping light at a desired spectral frequency to the active region).

In FIG. 1A, a VCSEL 100 is shown to include a substrate 102, a first reflector layered structure (or first reflector, for short) 104 overlying the substrate 102; a first spacer region 106 overlying the first reflector; an active region 108 overlying the first spacer region 106; a second spacer layer 110 overlying the active region 108; and a second reflector 112 overlying the active region 108. The spacer layer 106, active region 108, and spacer layer 110 define a cavity, and an associated cavity resonance wavelength. The substrate 102 is made from a semiconductor material possessing a corresponding lattice constant. Typically, the substrate 102 can include gallium arsenide (GaAs), or indium phosphide (InP), but other semiconductor substrates such as gallium antimonide (GaSb), germanium (Ge), or an epitaxially grown material (such as a ternary or quaternary semiconductor), or a buffered or composite substrate can also be used. The lattice constant of the substrate 102 is judiciously chosen to minimize defects in materials subsequently grown thereon. The reflector (or minor) 104 is typically a semiconductor DBR with a lattice matched to that of the substrate 102. A DBR is a periodic structure formed from alternating materials with different refractive indices that can be used to achieve high reflection within a range of frequencies or wavelengths. The thicknesses of the layers are chosen to be an integer multiple of the quarter wavelength, based on a desired design wavelength λ₀. That is, the thickness of a layer is chosen to be an integer multiple of λ₀/4n, where n is the refractive index of the material at wavelength λ₀. A DBR can include, for example semiconductor materials of Groups III and V of the periodic table such as, for example, AlAs, AlGaAs, GaAs, InAs, GalnAs, AlInAs, InGaP, AlInGaP, InGaP, InGaAsP, GaP, InP, AlP, AlInP, or AlInGaAs. When formed on a GaAs substrate, the DBR is formed using two different compositions for AlGaAs. Minor 104 can also be doped with an n-type dopant or a p-type dopant to facilitate current conduction through the device structure. A spacer layer 106, such as AlGaAs or AlGaInP may be formed overlying the first mirror 104. Active region 108 is formed overlying spacer layer 106 and includes a material capable of emitting a substantial amount of light at a desired wavelength of operation. It will be understood that active region 108 can include various light emitting structures, such as quantum dots, quantum wells, or the like, which substantially improve a light emitting efficiency of VCSEL 100. For a GaAs substrate, the active region 108 can include a material that can emit light between a wavelength of about 0.62 μm and 1.6 μm. Active region 108 can include more than one material layer, but is illustrated as including a single layer in the preferred embodiment for simplicity and ease of discussion. For example, active region 108 can include GaAs/AlGaAs or InGaAs/GaAs or AlGaInP/InGaP or GaInNAsSb/GaAsN multiple quantum wells (MQWs). A spacer layer 110, such as AlGaAs or AlGaInP may be formed overlying active region 108. A second reflector (or mirror) 112 may be formed overlying spacer layer 110. Second mirror 112 is typically a DBR and is similar in design to first mirror 104. When formed on a GaAs substrate, the DBR is formed using two different compositions for AlGaAs. Mirror 112 can also be doped with a p-type dopant or an n-type dopant, the doping type being opposite to the doping type of first mirror 104, in order to form a p-n junction and to facilitate current conduction through the device structure. In order to have efficient VCSEL operation, a method of confining the current laterally and/or confining the optical field laterally (providing waveguiding) is required, thus it is necessary to form a confinement region within VCSEL 100. In the example shown, confining region 114 is formed within VCSEL 100 and has material properties different from adjacent regions to provide waveguiding and/or to define a region for current injection such that lasing occurs in an aperture region 116 within confining region 114. Methods of forming confining regions include, but are not limited to, oxidation, proton implantation, ion implantation, semiconductor etching, semiconductor regrowth, deposition of other materials and combinations thereof. In the example shown, confining region 114 is formed using ion implantation to produce a highly resistive region, while defining the low resistivity aperture region 116 through which current can flow. VCSEL 100 is completed by a first metal contact 118 and a second metal contact 120. Either first metal contact 118 or second metal contact 120 has an opening or metal aperture 122 through which light can be emitted. In the example shown, light emission occurs through aperture 122 formed on the bottom of the substrate 102 but in other examples, light can be emitted through the top surface. Aperture region 116 has a first dimension and metal aperture 122 has a second dimension. Typically, the apertures are circular, and the dimension describing the aperture is the diameter, but other shapes can be used. In some embodiments, the first and second aperture dimensions are different, but in other embodiments they can be the same. The method used to form the device and its apertures align the apertures such that they are concentric and have rotational symmetry.

It will be understood that other layers such as current spreading layers and contacting layers can also be included, more than one confinement region at different depths within the device can be used, and that different electrical contacting configurations used, such as intracavity contacts. However, these have not shown for the sake of simplicity in order to clearly to explain key device design elements. Devices designs with concentric apertures and with symmetry are used to provide uniform current injection and optical guiding within the device.

FIG. 1B is similar to FIG. 1A, showing a cross section of a VCSEL 100′ using oxide confinement to define the aperture. As with the device in FIG. 1A, VCSEL 100′ includes substrate 102′, first mirror 104′, first spacer layer 106′, active region 108′, second spacer layer 110′ and second mirror 112′. In order to form a confinement region, a mesa structure 124′ is first etched using standard semiconductor etch methods, in order to expose a higher aluminum-containing layer or layers for oxidation, which can be achieved using known methods. For devices formed on GaAs substrate, the layer or layers for oxidation typically include Al_{y}Ga_{1-y}As, where y is greater than 0.9. The oxidation process forms confinement region 114′ that has (a) a low refractive index and (b) high resistivity, when compared to the unoxidized aperture region 116′, and therefore provides both optical and electrical confinement. Devices with oxide-confined apertures can have very low threshold currents. Aperture 116′ is typically circular, so as to form a circular current injection region and an associated output beam from VCSEL 100′, although other shaped apertures such as squares, or rectangles or diamonds may also be used. Aperture 116′ has a first dimension, which in the case of a circular aperture is the diameter. VCSEL 100′ is completed by a first metal contact 118′ and a second metal contact 120′. Either first metal contact 118′ or second metal contact 120′ has an opening or metal aperture 122′ through which light can be emitted. In the example shown, light emission occurs through aperture 122′ at the top surface of the device, but in other examples, light can be emitted through the bottom surface.

Metal aperture 122′ is typically circular, though can have other shapes, similar to aperture 114′, and has a second dimension that can equal the first dimension of aperture 114′ or be different to the first dimension of aperture 114′. The method used to form the device 100′ and its apertures 114′ and 122′ align the apertures such that they are concentric and have rotational symmetry. Thus for apertures of different size, the overlap region between the different apertures is the same on either side of the aperture. As with device 100 in FIG. 1A, it will be understood that other layers such as current spreading layers and contacting layers can also be included, more than one confinement region at different depths within the device can be used, and that different electrical contacting configurations used, such as intracavity contacts. However, these have not shown for the sake of simplicity in order to clearly to explain key device design elements. Devices designs with concentric apertures and with symmetry are used to provide uniform current injection and optical guiding within the device.

As mentioned previously, in certain applications, VCSELs operating with a single spatial mode are desired. However, the aperture sizes for such devices are typically small (around 6 to 8 μm diameter apertures) and have limited single-mode output powers. Larger area devices can offer higher output powers, but these will typically operate with multiple spatial (or transverse) modes. A problem with larger devices is that spatial mode transitions from one pattern of emission to another pattern of emission can occur at different current injections levels and are difficult to be able to control or predict. Larger area devices also operate at higher currents, and resistive heating effects can affect the mode performance of the devices.

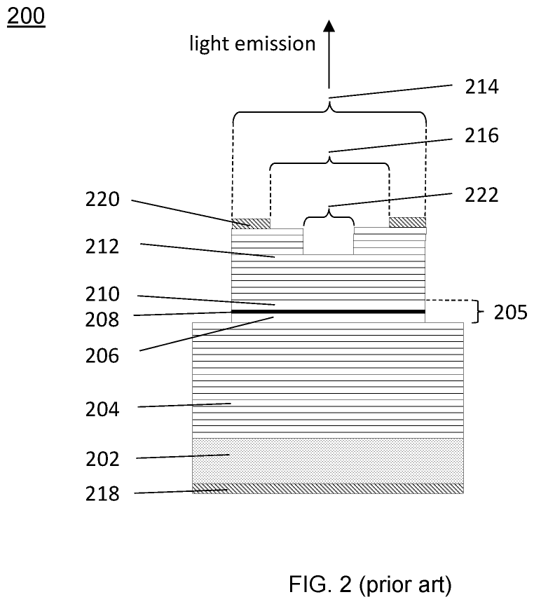

Therefore typically, specific structures are required in order to control the device modal performance. Multiple modes exhibiting a ring-shaped pattern can be useful in multimode fiber based optical communications, and controlled spot patterns may also be useful as structured light sources for imaging applications. FIG. 2 shows an example of a related-art VCSEL 200, and designed to produce a ring-shaped mode. VCSEL 200 is similar to VCSELs 100 and 100′, except the guiding in this device is optical guiding provide by an etched pillar 214. The top metal contact 220 has an aperture 216 which has a diameter smaller than the diameter of the etched pillar 214. Within aperture 216, an etched region 222 is formed having a diameter lesser than the diameter of aperture 216. Etched region 222 is centered within aperture 222, so as to maintain concentric designs, with rotational symmetry. The purpose of etched region 222 is to reduce the number of mirror pairs at the center of the device, which reduces the optical feedback in the etched region. The reflectivity of the mirror is higher in the area between etched region 222 and aperture 216 such that ring-like modes can be produced. Designs such as this are described in U.S. Pat. No. 5,963,576. Problems with this design include the necessity for additional processing steps including etching away mirror pairs within a device aperture, as well as exposure of aluminum-containing layers which could then exhibit oxidation and affect device reliability. While other techniques exist, as described in PCT application WO2012/140544, this requires more complex device designs and processing, involving two etched structures and two oxidation regions within a single layer to define a ring-like mode. Again, the designs are concentric and have rotational symmetry.

Accordingly, a problem of ensuring a multi-mode lasing (that is, producing a light output, containing multiple and/or high-order spatial modes from) of an individual VCSEL device or an array of VCSEL devices, while gaining control of preventing the operation of such device or array of devices in a single-spatial-mode regime is solved by devising a VCSEL structure with at least one of a) a reduced or at least frustrated—as compared with the conventionally-manufactured VCSEL devices—rotational symmetry of the VCSEL structure; and b) a deliberately-introduced transverse or lateral (i.e., along a layer) misalignment between physical apertures defined in different layers of the VCSEL structure and configured to spatially-contain at least one of the spatial distribution of current injection throughout the VCSEL structure and the spatial distribution of the light output generated by the VCSEL device in operation. In one case, the rotational symmetry may be defined with respect to the longitudinal axis of the structure that is transverse to the layers of the structure, while one physical aperture is defined by a spatially-patterned metal layer configured as an electrical contact of the VCSEL structure. Spatial patterning of other VCSEL components (that are not intended to be electrically active, such as for example substrate patterning, or deposition of additional spatially-patterned dielectric layers) may be used in conjunction with the patterned optical output aperture to facilitate the output beam control.

The idea of the invention stems from the realization that fabrication of a practically-functional multimode (or multiple spatial output) VCSEL devices can be achieved through introduction of asymmetry into the structure of the device aperture. In one implementation, for example, the apertures present in the VCSEL layered structure may have no more than two axes of symmetry, and/or the apertures may be non-coaxial with respect to each other or laterally offset with respect to each other.

Implementations or embodiments of the idea of the invention address problems associated with existing multimode VCSEL devices. The judicial configuration of the apertures in VCSEL layers can be achieved through conventional and simple processing steps while avoiding additional complex processing steps that are common in the manufacturing practice and that can affect device reliability.

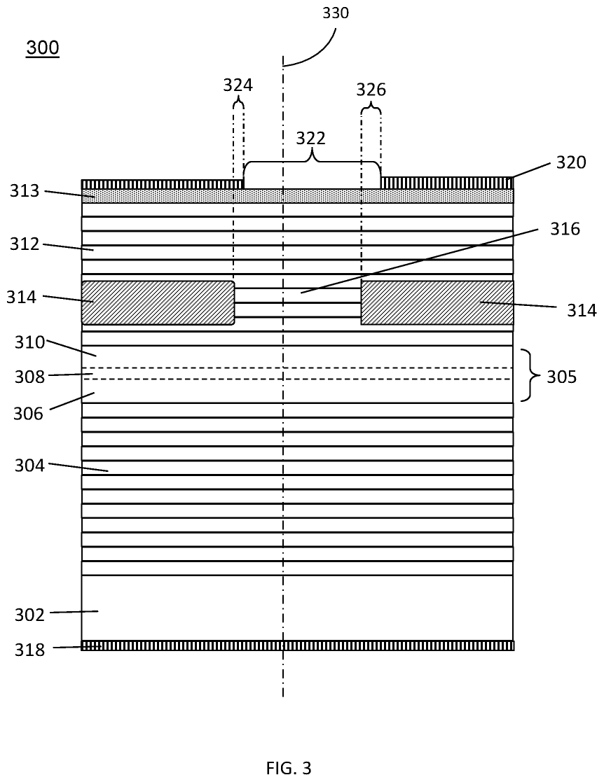

FIG. 3 presents a sectional view of an example of a VCSEL 300, structured according to the idea of the invention. VCSEL structure 300 includes a substrate 302, a first mirror or reflector 304 (configured as a DBR, in one implementation) that is overlying the substrate 302, a first spacer layer 306 overlying the first reflector 304, an active region 308 (shown by dashed lines) carried by the first spacer layer 306, a second spacer layer 310 overlying the active region 308, and a second mirror or reflector structure 312, also overlying the active region. A contact layer 313 is disposed to be carried by the second mirror 312. In general, and unless explicitly stated otherwise, as broadly used and described in this application, the reference to a layer or element as being “carried” on a surface of an element or another layer refers to both a layer that is disposed directly on the surface of the element/layer or a layer that is disposed on yet another coating, layer or layers that are disposed directly on the surface of the element/layer. The spacer layer 306, active region 308, and spacer layer 310 define a cavity 305 defining an associated cavity resonance wavelength.

The substrate 302 is a semiconductor substrate having a corresponding lattice constant. Typically, the substrate 302 can include gallium arsenide (GaAs), or indium phosphide (InP), but other semiconductor substrates such as gallium antimonide (GaSb), germanium (Ge) or an epitaxially grown material (such as a ternary or quaternary semiconductor), or a buffered or composite substrate, such as a rare-earth oxide buffered silicon substrate can also be used. The lattice constant of substrate 302 is judiciously chosen to minimize defects in materials subsequently grown thereon. Substrate 302 may be doped, which allows formation of a contact metal on the lower surface of substrate 302. In some embodiments (not shown), the substrate may be undoped, and a contact layer can be formed on the substrate to facilitate formation of a lower metal contact for the VCSEL.

The reflector 304 is shown as a semiconductor DBR formed with a lattice substantially matched to that of the substrate 302. A DBR is a periodic structure formed from alternating layers of materials with different refractive indices that can be used to achieve high reflection within a range of frequencies or wavelengths. The thicknesses of the layers are chosen to be an integer multiple of the quarter wavelength, based on a desired design wavelength Xo. That is, the thickness of a layer is chosen to be an integer multiple of λ₀/4n, where n is the refractive index of the material at wavelength λ₀. A DBR can include, for example semiconductor materials of Groups III and V of the periodic table such as, for example, AlAs, AlGaAs, GaAs, InAs, GalnAs, AlInAs, InGaP, AlInGaP, InGaP, InGaAsP, GaP, InP, AlP, AlInP, or AlInGaAs. When formed on a GaAs substrate, the DBR is formed using two different compositions for AlGaAs. Reflector 304 can also be doped with an n-type dopant or a p-type dopant to facilitate current conduction through the device structure. A spacer layer 306, such as AlGaAs or AlGaInP may be formed overlying the first mirror 304. Active region 308 is formed overlying spacer layer 306 and includes a material capable of emitting a substantial amount of light at a desired wavelength of operation. It will be understood that active region 308 can include various light emitting structures, such as quantum dots, quantum wells, or the like, which substantially improve a light emitting efficiency of VCSEL 300. For a GaAs substrate, the active region 308 can include a material that can emit light between a wavelength of about 0.62 μm and 1.6 μm. Active region 308 can include more than one material layer, but is illustrated as including a single layer in the preferred embodiment for simplicity and ease of discussion. For example, active region 308 can include GaAs/AlGas or InGaAs/GaAs or AlGaInP/InGaP or GaInNAsSb/GaAsN multiple quantum wells (MQWs). A spacer layer 310, such as AlGaAs or AlGaInP may be formed overlying active region 308. A second reflector 312 may be formed overlying spacer layer 310. Second reflector 312 may also be a DBR and, in this case, may be similar in design to that of the first mirror 304. When formed on a GaAs substrate, the DBR is formed using two different compositions for AlGaAs. Reflector 312 can also be doped with a p-type dopant or an n-type dopant, the doping type being opposite to the doping type of first mirror 304, in order to form a p-n junction and to facilitate current conduction through the device structure. Contact layer 313 is formed on reflector 312 and is a doped semiconductor layer that facilitates electrical connection of the device with a metal contact layer.

In order to ensure the efficient operation of the VCSEL device, the lateral confinement (in a plane that is transverse to the axis z of the local system of the device coordinates) of the current and/or of the optical field (by providing waveguiding, for example) may be required. Accordingly, a confining region or layer 314 within the VCSEL 300 is formed, for example, by structuring the material properties of the embodiment 300 to be different from those of the adjacent regions: to provide optical waveguiding and/or to define a region for current injection such that lasing occurs through an aperture region or opening 316 defined within the confining region 314. Methods of forming the confining region include, but are not limited to, oxidation, ion implantation, semiconductor etching, semiconductor regrowth, deposition of other materials and combinations thereof. In one implementation of the VCSEL 300, the confining region 314 is formed using ion implantation to produce a highly electrically-resistive layer, while at the same time defining the low electrical resistivity aperture area 316 through which current can be directed. It will be understood that other functional layers (such as current spreading layers and contacting layers) can also be appropriately included, that more than one confinement region or layer at different depths within the device 300 can be formed, and that different electrical contacting configurations (such as intracavity electrical contacts) may be used. (These variations from the schematic structure 300 are not shown for simplicity of illustration and in order to clearly to explain key design elements of the device.) The VCSEL structure 300 is shown to contain a first metal contact layer 318 and a second metal contact layer 320. As shown, each of these contact layers is located at a periphery, a boundary of the stack of the layered structure defining the embodiment of VCSEL, and is defined, therefore, as a peripheral layer. Either the first metal contact layer 318 or the second metal contact layer 320 (here, as shown—the layer 320) has an opening or aperture 322 through which light can be emitted by the VCSEL 300 in operation of the device.

Whereas in VCSEL structure 100 of the related art the aperture region 114 and metal aperture are aligned to be coaxial with one another, aperture opening 316 (defined in the confining layer 314) and the aperture 322 in the metal contact layer are offset in at least one lateral direction with respect to one another (that is, the axes of these two apertures are spatially shifted with respect to one another along an axis that is transverse to the direction of the output beam: here—along an x-axis and/or a y-axis). As a result, these two aperture openings are no longer coaxial (with respect to the z-axis). The aperture openings 316 and 322 are typically circular in shape, and can be characterized by corresponding dimensions, such as diameters. In the case when each of the aperture opening 316, 322 is rotationally symmetric, the introduction of the lateral or transverse offset therefore reduces or frustrates the rotational symmetry of the overall device 300. While the diameters of the apertures 316, 322 can be substantially equal, these diameters can also differ from one another. In the example shown in FIG. 3, the aperture 322 is larger than the aperture 316. Consequently, since these apertures are not coaxial, the difference between the diameters of the apertures 316 and 322 leads to a first offset 324 on one side of the longitudinal axis 330 of the device 300, where the metal contact layer 320 overlaps with (hangs over) the aperture opening 316, and a second offset 326 on the opposite side of the aperture 316 (as shown—on the right-hand side with respect to the axis 330). The first lateral offset 324 is smaller than it would be in the case of coaxial alignment between the apertures 316, 322, and the second lateral offset 326 is larger than it would be if the apertures 316, 322 were coaxial. The practical effect produced by of these spatial offsets in operation of the device 300 is to cause a non-uniform spatial profile of current injection into the aperture region 316. The aperture or opening-discontinuity formed in a confining layer (such as the aperture or aperture region 316 in the layer 314, for example), may be interchangeably referred to as a “confining aperture”, a “confinement aperture”, or an “internal aperture”.

As a result of the spatially non-uniform current injection profile, the position of the spatial mode is transversely offset from the center of output aperture 322 and/or confining aperture 316. This is due to a carrier-concentration-dependent gain variation across the aperture 316, and guiding effects within the apertures 316 and 322 caused by a combination of a refractive index variation across the active region due to the carrier concentration variation across the aperture 316, (where the refractive index decreases with increasing carrier concentration), and thermal guiding effects associated with resistive losses for the current injection that varies across apertures 316 and 322 (with refractive index increasing with temperature). Under pulsed operating conditions, the carrier-induced anti-guiding effect can cause spatial mode or filament formation in one or more locations within the aperture. With increase of the pulse duration during the operation of the device—and as the device transitions towards the continuous-wave (CW) operation—the thermal effects caused by the resistive heating increase and dominate the guiding mechanisms, thereby allowing the spatial modes or filaments to form in different spatial regions of the aperture 322. Accordingly, by judiciously choosing the current injection conditions, one can gain the control of the (asymmetric) mode or filament formation in different locations within the aperture, thereby making it possible to switch between different spatial output distributions (patterns) of light during the operation of the device. The existence of different spatial patterns (modes or filaments), and the switching between them can be used. In one embodiment, to reduce the spatial coherence of the light-output of the device and to reduce the speckle contrast for a single, individual VCSEL device.

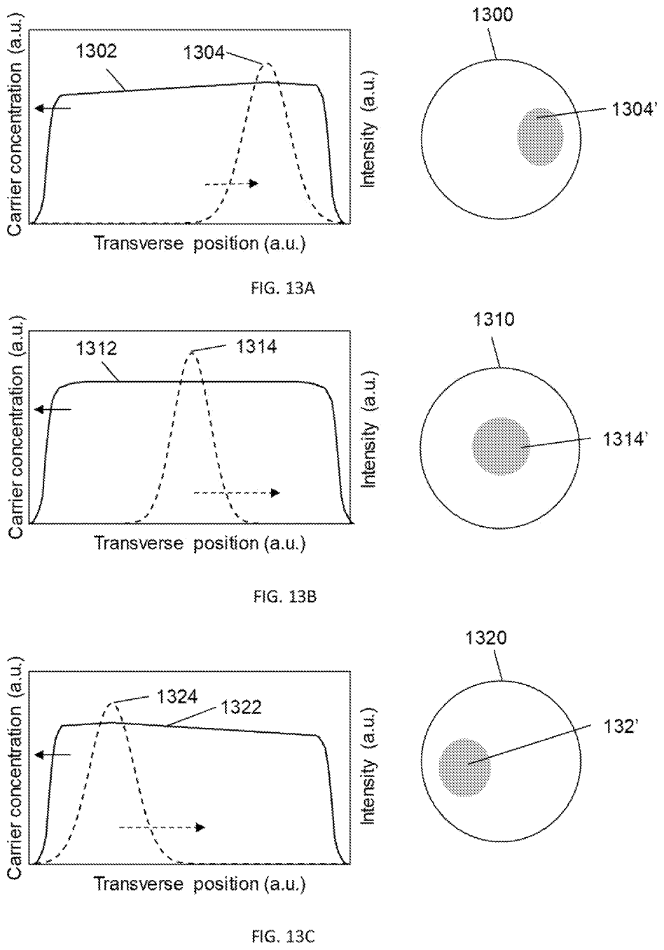

Asymmetry in the structure of a VCSEL device causes a spatially non-uniform current injection that gives rise to a non-uniform carrier concentration. This, in turn, affects the locale or space occupied by lasing mode(s) (or filament(s)). This is shown schematically in FIGS. 13A, 13B, 13C for three different VCSEL structures having three different transverse offsets between the confining aperture and the emission (output) aperture. Each of FIGS. 13A, 13B, 13C contains two portions: schematic plots (illustrating the lateral distribution of carrier concentration and the lowest lasing mode across the VCSEL structure) and a simplified top view showing the spatial coordination of the output aperture and the lasing mode.

FIG. 13A, in particular, illustrates schematically that for an emission or output aperture 1300, a spatial mode 1304′ (or 1304) is at a particular location offset to the right of the center of the aperture (as seen in the Figure). Viewing a cross-section of the aperture across the mode, in the local coordinate system, the carrier concentration across the aperture 1302 is non-uniform and is higher at the right side of the aperture. Consequently, the threshold carrier concentration required for lasing occurs at this particular offset location, giving rise to a lasing mode with a peak 1304, corresponding to spot 1304′ in the right-hand-side portion of FIG. 13A. In comparison, FIG. 13B shows that for an output aperture 1310 that is not laterally offset with respect to the confinement aperture of the corresponding VCSEL structure, the carrier concentration 1312 across the cavity is substantially uniform, resulting in formation of the lasing mode practically at the center of the output aperture (as indicated by peak 1314 and spot 1314′). FIG. 13C shows that for an emission/output aperture 1320 (which is laterally offset, with respect to the confining aperture of the correspondence VCSEL structure in a fashion different from that of FIG. 13A), a spatial distribution of lasing mode 1324′ (or 1324) is offset towards the location to the left of the center of the aperture. Viewing a cross-section of the output aperture across the mode, the carrier concentration 1322 across the aperture is substantially non-uniform and is shown higher at the left side of the aperture. Consequently, the threshold carrier concentration required for lasing occurs at this particular location, giving rise to a lasing mode with a peak 1324, corresponding to spot 1324′. In an array of equally spaced VCSEL structures with apertures 1300, 1310 and 1320, the spatial coordinates of the lasing modes emanating from these apertures have unequal spacing between themselves, thereby forming modes of the adjacent devices.

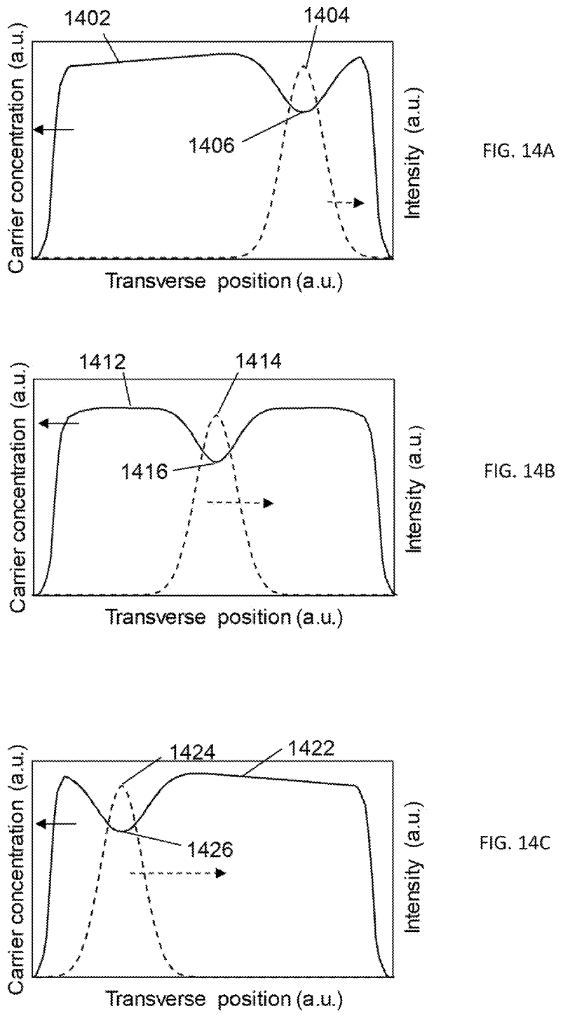

As the injection current provided to the laser device is increased, the carrier concentration becomes substantially pinned at the location of the formation of the lasing mode, while increasing elsewhere. The carrier concentration can even become reduced at the location of mode formation. This is schematically illustrated in FIGS. 14A, 14B, 14C where curved 1404, 1414 and 1424 representing lasing modes (of the structured of FIGS. 13A, 13B, 13C, respectively) coincide with “dips” or reductions in the carrier concentration distributions 1402, 1412 and 1422 at positions 1406, 1416 and 1426. As a result, the refractive index profiles across the devices provide for a higher refractive index at locations 1406, 1416 and 1426 that serves to spatially converge or focus the modes 1404, 1414 and 1424. Such “focusing” can cause local depletion of carriers in the material and a “collapse” of the mode at that location, while the rising carrier concentration elsewhere in the device allows a threshold carrier density to be achieved at a different location (which, in turn, leads to formation of a higher order transverse mode or spatial filament at the different location).

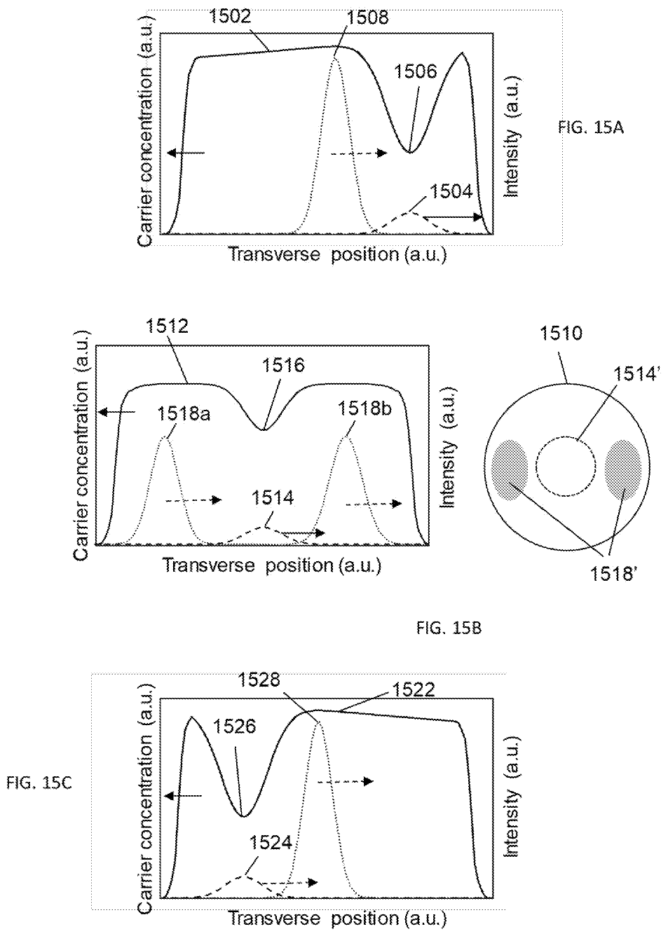

The formation of a higher order transverse mode or spatial filament is depicted schematically in FIGS. 15A, 15B, and 15C, which are now compared with respectively corresponding FIGS. 13A through 13C and 14A through 14C. As a person of skill in the art will readily appreciate, and in reference to FIG. 15A, as the decrease or dip 1506 in the spatial concentration of the carrier concentration 1502 becomes more pronounced, the lasing mode 1504 is no longer supported due to “spatial hole burning”, and the intensity of the lasing mode decreases (possibly, up to the point of becoming eventually extinguished). Instead, a new lasing mode or filament 1508 forms elsewhere in the cavity, at the location determined by the asymmetry of the current injection caused by the aperture offset as well as waveguiding effects. For a VCSEL aperture 1510/1310 (disposed with no offset with respect to the corresponding confining aperture), the initially-lasing mode 1314 collapses to what is denoted as mode 1514 (or 1514′) and a new “dumb-bell” like shaped mode indicated by intensity peaks 1518a and 1518b (and associated mode spots 1518) is formed. As shown in FIG. 15C, the initially-lasing mode 1324 is no longer supported (and degenerated to mode 1524) as the decrease or dip 1526 in the carrier concentration distribution 1522 continued to grow, and the new mode 1528 forms elsewhere across the emission/output aperture. Therefore, even at higher current injection levels for an array of equally spaced devices with apertures 1300, 1310 and 1320 shown in FIG. 13, the mode location emanation from each of the constituent output apertures of the array still occurs at a different spatial location, thereby causing unequally spaced modes from the adjacent constituent devices of the array.

Under some current injection operating conditions, more than one spatial mode can exist, each of such multiple modes typically occurring at a slightly different wavelength. Consequently, the degree of coherence of the superposition of all transverse modes or filaments within a device aperture (or an array of devices) is reduced, which in turn reduces the speckle contrast produced by a device (or an array of devices). Multi-spatial mode (or multi-filament) operation of the individual VCSEL device (or an array of VCSEL structures) is therefore advantageous for applications including 3D imaging, illumination, object or gesture recognition, LIDAR, optical coherence tomography (OCT) and interference microscopy.

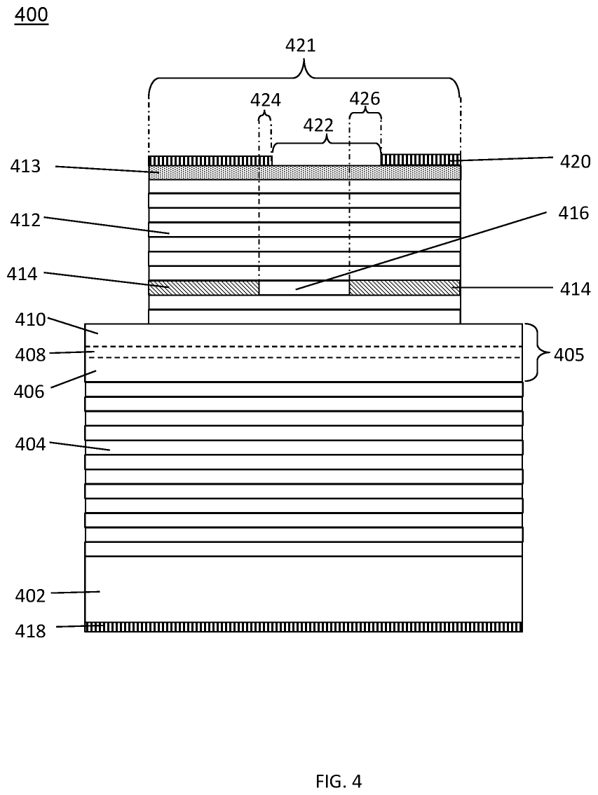

FIG. 4 is a sectional view of an example of a VCSEL 400, structured according to the idea of the invention. VCSEL 400 is similar to VCSEL 300, except it uses an oxide-confined aperture. As with VCSEL 300, only certain layers are shown for the sake of clarity in order to describe the inventive features. VCSEL 400 includes a substrate 402, a first mirror 404 overlying the substrate, a first spacer region 406 overlying the first reflector layer, an active region 408 overlying the first spacer layer, a second spacer layer 410 overlying the active region and a second mirror 412 overlying the active region. A contact layer 413 overlies second reflector 412. Spacer layer 406, active region 408 and spacer layer 410 define a cavity 405 that has an associated cavity resonance wavelength. In order to form a confinement region, a mesa structure 421 is first etched using standard semiconductor etch methods, in order to expose a higher aluminum-containing layer or layers for oxidation, which can be achieved using known methods. For devices formed on GaAs substrate, the layer or layers for oxidation typically include Al_{y}Ga_{1-y}As, where y is greater than 0.9. The oxidation process forms confinement region 414 that has (a) a low refractive index and (b) high resistivity, when compared to the unoxidized aperture region 416, and therefore provides both optical and electrical confinement. Aperture 416 is typically circular, so as to form a circular current injection region, although other shaped apertures such as squares, or rectangles or diamonds may also be used. Aperture 416 has a first dimension, which in the case of a circular aperture is the diameter. VCSEL 400 is completed by the peripheral layers—a first metal contact layer 418 and a second metal contact layer 420. Generally, either first metal contact layer 418 or the second metal contact layer 420 is structured to contain an opening therethrough—an aperture 422 (also referred to as a metal aperture) through which light is emitted during the operation of the device. In the example shown, light emission occurs through the aperture 422 in the peripheral layer 420 at the top surface of the device, but in other examples, light can be emitted through the bottom surface.

In one implementation the metal aperture 422 is made circular, though it can have other shapes in related embodiments (similarly to the aperture 414), and can be dimensioned such as to equal, in size, to the aperture 414 (or, alternatively, be sized differently from the aperture 414).

The method used to form the device 400 and its apertures 414 and 422 introduces a lateral offset in at least one direction, such that the apertures such are non-concentric and the device does not have rotational symmetry. In the example shown, aperture 422 is larger than aperture 414. Consequently, this leads to a first offset 424 on one side of the aperture, where the metal 420 overlaps with aperture 416, and a second offset 426 on the opposite side of the aperture, where the offset between the metal 420 and the aperture 416 is larger than if the apertures were aligned concentrically (or coaxially with respect to axis z). The effect is to create a non-uniform current injection profile into the active region of VCSEL 400, as described above for VCSEL 300, in order to produce multiple transverse modes or output filaments.

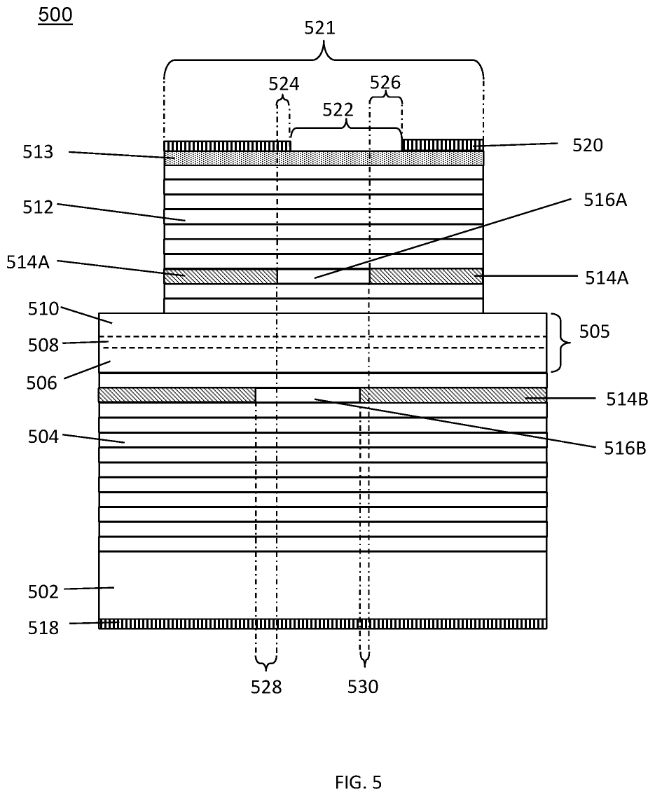

FIG. 5 is a schematic of another embodiment of the VCSEL 500, structured according to the idea of the invention. The structure of the VCSEL 500 is similar to that of VCSEL 400, except it has two confining layers or regions (514A and 514B), as shown—on opposing sides of the cavity region 505. The confining region 514A defines an opening or aperture 516A, and the confining region 514B defines the aperture 516B. The sizes of the apertures 516A, 516B can be equal or different from one another. The spatial alignment between the metal aperture 522 in the peripheral contact layer 513 and the aperture 516A is made to be substantially the same as in the case of the embodiment 400 of FIG. 4, that is with a lateral offset, with respect to the longitudinal axis of the embodiment 500 in at least one direction (along at least one of the axes x- and y-) to define an offset 524 on one side of the aperture 516A and an offset 526 on the other side of the aperture 516A. The aperture 516B is shown similarly transversely shifted with respect to the aperture 516A and the aperture 522 to define a first offset 528 on one side with respect to aperture 516A, and a second offset 530 on the second side of the aperture 516A. In some related embodiments, the geometrical cooperation among these apertures 516A and 516B can be different—for example, these apertures can be substantially coaxially aligned with respect to one another while, at the same time, not being coaxially aligned with the aperture 522. It is preferred that in an embodiment of a VCSEL device having an output aperture and at least two confining layers with corresponding apertures, at least two of these three apertures be non-coaxial with one another.

The operational effect, produced by the lack of mutually-coaxial alignment between at least two of the three apertures in the VCSEL device structure that does not have rotational symmetry, is that a spatial profile of the current injection into the active region of the VCSEL 500 is non-uniform, as was already described above in reference to FIG. 3 (VCSEL 300), in order to form multiple transverse modes or output filaments of the light output produced by the VCSEL device.

A person of skill in the art will readily appreciate, therefore, that single, individual VCSEL devices employing aperture offsets, according to the idea of the invention, can generate multiple transverse (or spatial) modes, thereby improving or reducing, as was already discussed, the speckle contrast associated with the light output of a conventionally-structured single VCSEL source. In many imaging applications, a combination of multiple VCSELs in either 1-dimensional or 2-dimensional arrays may be required. In a VCSEL array formed using the “aperture offset” designs, the offset between the aperture(s) in the confinement layer(s) and the metal aperture(s) in the peripheral layer(s) can be changed from one device to another, such that the spatial mode properties of different devices within the same array are dissimilar. In the so-constructed array of VCSELs, some of the constituent VCSEL devices may still have output metal apertures and the apertures in the confining layers that are coaxial with one another at least because the modal behavior of the light output produced by such constituent VCSELs is still different from that of the light output produced by other devices the apertures of which are not coaxial. In an array of VCSELs, the inclusion of constituent devices with at least two different aperture offsets (also referred to as aperture patterns) can be used to vary the spatial mode pattern across an array, and to further improve speckle contrast.

A person of skill in the art will also appreciate, that devices employing aperture offsets, according to the idea of the invention, can also include vertical external-cavity surface-emitting lasers (VECSELs) configured to generate multiple transverse (or spatial) modes, thereby improving or reducing, as was already discussed, the speckle contrast associated with the light output of a conventionally-structured single VECSEL source. In a VECSEL, an aperture may be implemented, for example in an external reflector or mirror that forms the extended cavity.

Embodiments of VCSEL devices of the invention are dimensioned and referred to in relation to the size of the smallest confinement aperture within a given device, which is usually formed by oxide confinement, or ion implantation, as previously described. VCSELs can have apertures between about 3 μm and 50 μm wide, and the apertures are typically circularly shaped, though they may also be formed to be square, rectangular, or elliptical. In some embodiments, the “VCSEL size” (in terms of the confinement aperture width) is between about 6 μm and about 25 μm, or between about 8 μm and about 20 μm. The metal aperture through which light is emitted (the output aperture) is appropriately dimensioned to be between about 3 μm and about 60 μm wide, or between about 8 μm and about 30 μm wide, or between about 10 μm and about 24 μm wide in related embodiment and typically has the same shape as that of the confinement aperture. For a top emitting device (that is, an embodiment in which the output aperture is formed in the metal contact layer at the top of the overall structure—such as the layer 520 of the embodiment 500, for example) , the output aperture typically has the same width as that of the confinement aperture, or is larger than the confinement aperture by, for example, 6 μm or less. For a bottom emitting device (that is, a device in which the output aperture is formed in the metal contact layer such as the layer 518 of the embodiment 500, for example), where current can be injected and spread through the substrate, the output aperture can be 10 μm or even up to 20 μm larger than the confinement aperture.

VCSEL structures have a first aperture (chosen from a combination of the output aperture and the at least one confining aperture) that has a first dimension, and a second aperture (chosen, from the same combination) that has a second dimension. A difference between the first and second dimensions satisfies at least one of the following conditions: a) this difference is equal to or smaller than 6 μm; b) this difference is equal to or smaller than 4 μm; and c) this different is equal to or smaller than 2 μm.

The lateral offset between the center of the confinement aperture and the center of the output aperture of an embodiment of a single, individual VCSEL device—which can be represented as a transverse offset between the respective axes of these two apertures, perpendicular to the layers in which the apertures are formed—can be at least 1 μm and up to 40% of the dimension of the confinement aperture. As a non-limiting example, for a 10 μm diameter device, the lateral offset of the metal output aperture with respect to the confinement aperture can be between about 1 μm and 4 μm. In some embodiments, the offset between the aperture centers can be up to 30% or 20% of the width of the confining aperture.

In some embodiments, devices configured according to an embodiment of the invention are structured to emit light from at least two different spatial locations within the same output aperture.

In some embodiments, devices configured according to an embodiment of the invention are devised to generate light with a spectral width (full-width-half-maximum, FWHM) of greater than 0.5 nm, or greater than 1 nm, or greater than 1.5 nm.

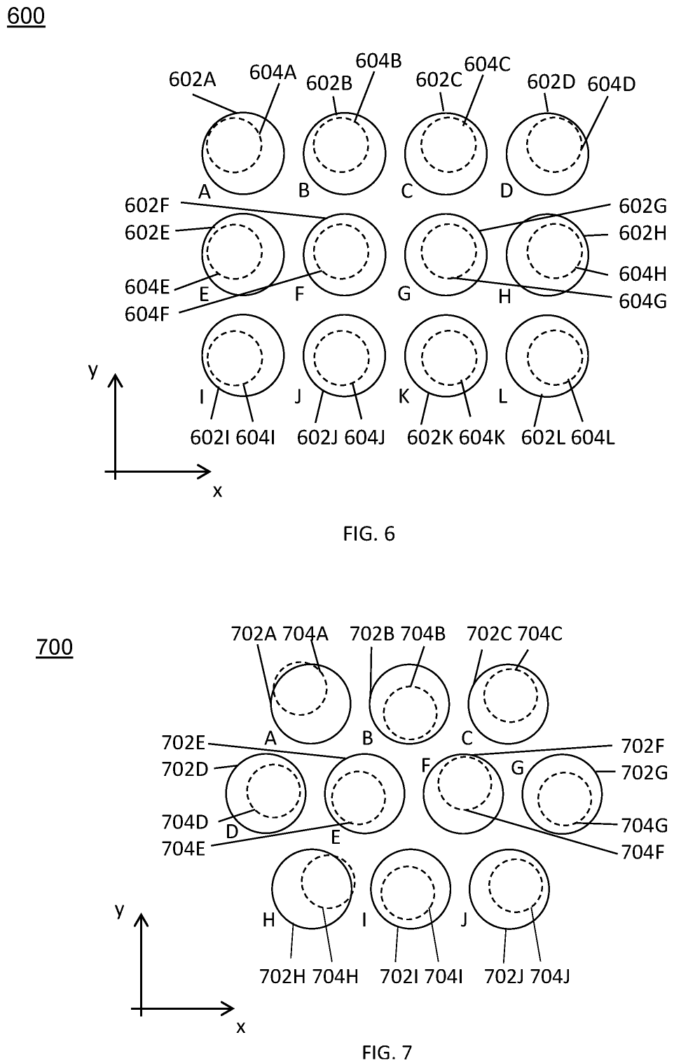

FIG. 6 shows a top view of a VCSEL array 600 formed using multiple constituent VCSEL device with two apertures each, according to the embodiment of the invention. (These two apertures are chosen from a combination of the output aperture and at least one confining aperture, that is at least one aperture formed in at least one layer of confining material) that are transversely offset with respect to one another, as shown by solid and dashed circular lines. The transverse offset between the apertures (shown as a geometrical offset between the dashed and solid line circles) is defined in a plane that is substantially perpendicular to a longitudinal axis of a given constituent VCSEL device. (In FIG. 6 such longitudinal axis is substantially parallel to the z-axis.) As shown, the longitudinal axes of the constituent devices of the array 600 are disposed on a substantially rectilinear grid. The specific embodiment of the VCSEL array 600 is illustrated to have three rows and four columns of the constituent devices labelled as A, B, C, D, . . . , K, and L. The dimensions of the output and the at least one confining aperture of each of the devices are different from one another.

In a specific embodiment of the array 600, the first aperture is the output aperture(s) of the constituent devices can be aperture(s) made in metal contact layer(s) corresponding to the light-emitting surface(s) of the constituent VCSEL devices. The second aperture is the at least one of the confining aperture(s) formed in the internal (to the structure of the device) layer configured to confine the spatial distribution of current within the VCSEL structure during the operation of the array. In another specific embodiment, both the first and second apertures are confining apertures that are internal to the structure of the VCSEL device and that are oxide-confined apertures or ion-implanted apertures.

In one embodiment, the device A has a first aperture 602A that is a metal (output) aperture 602A, and a second aperture 604A that is a confining aperture. The apertures of the constituent devices B through L are defined in a similar fashion. As shown, the sizes (and shapes) of the first apertures of different constituent devices are substantially equal to one another and the sizes (and shapes) of the second apertures of the individual constituent devices are substantially equal to one another, while a given first aperture is larger than the respectively corresponding second aperture. Generally, however, the corresponding aperture sizes for constituent devices in the array do not have to be the same.

Stepping across a row of array the constituent devices from device A to device D, for example—it can be seen that the lateral offset between the first and second apertures is systematically changed along the row. Stepping down a column of the array (for example, from device A to device I), it can be seen that the lateral offset between the first and second apertures is also systematically changed in the direction of the column. Thus, the constituent devices within a given array can be configured to have non-coaxial apertures that have different offsets with respect to one another, thereby causing different spatial profiles of current injection for the constituent lasers and hence different content of spatial modes in outputs from different constituent lasers. In this example, while the offsets between the apertures of the constituent devices are generally systematically varied in the x-direction and/or the y-direction across the overall array, it is possible that at least one constituent device in the array has coaxially-aligned first and second aligned apertures, while at least one constituent device in the array has non-coaxial first and second apertures. As a result, the different spatial modes at the output from the different lasers of the array form spatially-multimode light emission with differing patterns, which patterns can be judiciously manipulated by changing offsets between the axes of the first and second apertures to achieve differently-shaped output beams from the VCSEL-arrays, as will be described later.

FIG. 7 schematically shows, in top view, another embodiment of a VCSEL array 700, with constituent VCSEL devices (denoted as A, B, C, D, E, F, G, H, I, and J) formed on a substantially hexagonal grid. In this example, device A has an output aperture and at least one confining aperture, one of which is denoted as a first aperture 702A and the other of which is denoted as a second aperture 704A. In this example, the offset between adjacent devices in the array is not systematically varied, as in the example of the VCSEL array 600, but is randomly selected. Again, the spatial emission pattern will vary from device to device and will result in non-equally spatially separated modes from the devices in the array so as to produce an “irregular” output pattern from the array.

In some examples, the aperture offsets can be designed according to a desired pattern in order to control beam output from various locations of the device array. At least one device in the array (or segment of an array) has non-concentrically aligned apertures. In other examples, the devices and their apertures are irregularly spaced. In other examples, the array of devices can be segmented such that different portions of the array can be used separately from each other or can be used together, according to the illumination requirements (such as required power or patterning or direction of the beam) for a given application.

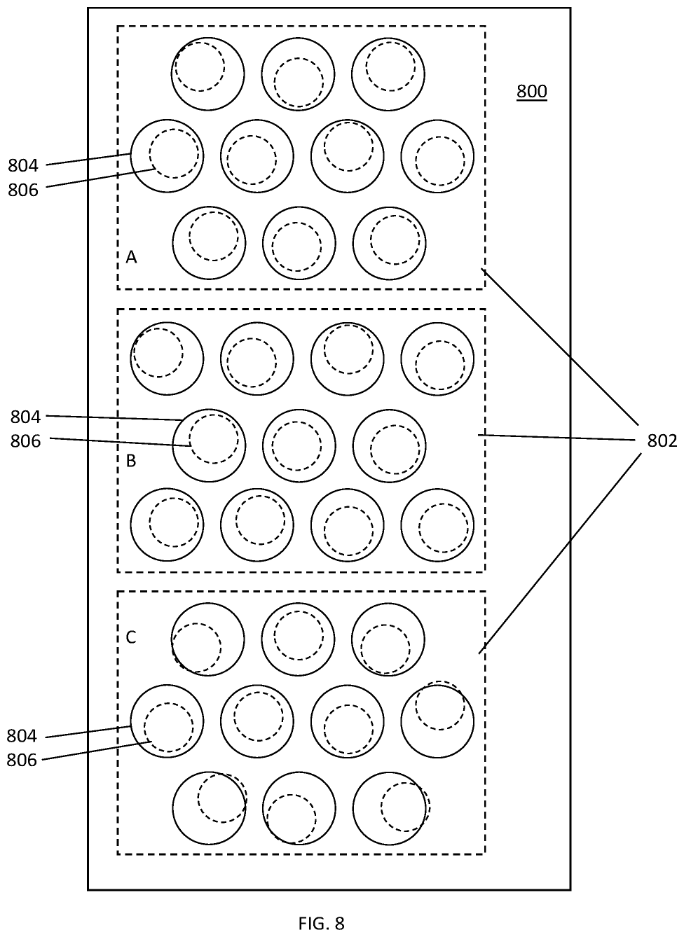

FIG. 8 shows a simplified top view of a segmented VCSEL array 800. The array is segmented into separate regions 802, each individual segment having one of more VCSEL devices or apertures. In this example, different segmented regions are denoted A, B, and C. Within each segment, the VCSEL devices have first and second apertures 804 and 806, as shown, with at least one device in an array segment having non-concentric apertures, and with the array having VCSELs with at least two different aperture offsets. The pattern of VCSEL apertures between different segments of the array can be different, and systematic, random or patterned offsets (for example, as shown in FIGS. 6 and 7) can be used. The apertures can be regularly spaced or irregularly spaced. Segments A, B and C may be individually electrically addressed, such that current can be driven through the VCSELs in an array segment in parallel. Segments may be addressed individually or in combination with each other. Operating several segments together can increase the power emitted by the laser array. In some embodiments, since the segments do not need to be identical and can have different device patterns and offsets, operating segments of the array separately can produce different array beam output patterns and shapes, according to the specific design of the apertures within a segment.

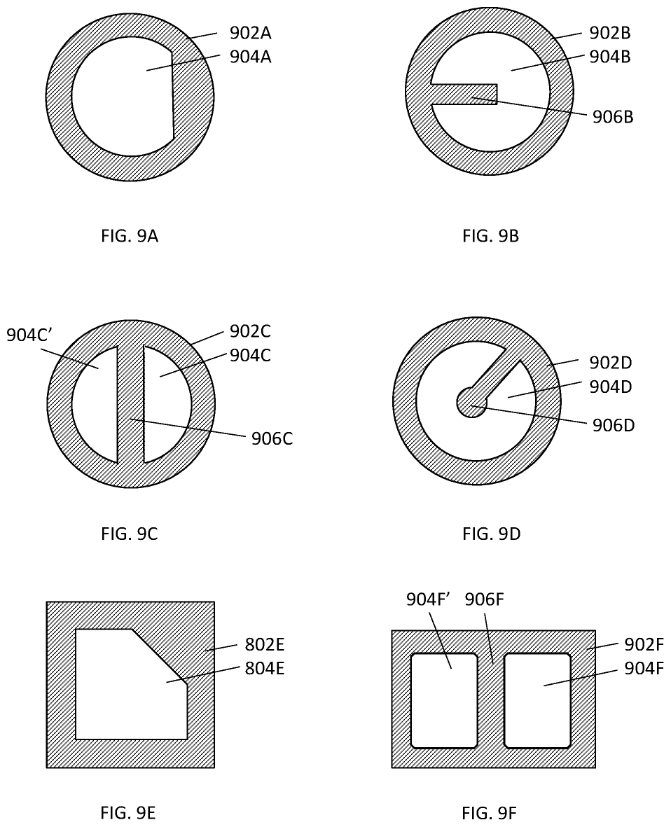

FIGS. 9A, 9B, 9C, 9D, 9E, and 9F provide schematic illustrations of spatial patterns according to which metallic layer(s) of a given embodiment of a VCSEL device (similar to the metal contact layer 320 of the embodiment 300, for example) can be structured to form output apertures or aperture openings (similar to the aperture 322, for example) that are dimensioned according to embodiments of the invention. According to the idea of the invention, the patterning of the metal aperture through standard lithography processes introduces asymmetry into the resulting output aperture and reduces the symmetry of the output aperture in the plane of the output aperture to that having at most two axes of symmetry. The confining aperture(s) in the confining layer(s) of a given device (such as the aperture 316 of the embodiment 300), not shown here, may be coaxially or non-coaxially aligned with the (metal) output aperture(s). Therefore, in an embodiment of the VCSEL device, the device asymmetry may be introduced solely through the appropriate shaping of the (metal) output aperture. In different embodiments, at least one of the confining apertures (that is, an area, in corresponding confining layers, that possess lower electrical resistivity than the surrounding areas of the same confining layers) can be defined by oxygen content in such aperture (i.e., the second portion of the layer containing the aperture). In related embodiments, as a result of the fabrication process during which identified portions of a given confining layer are exposed to ion implantation procedure, the lattice structure of the so-treated confining layer outside of the bounds of the area of the confining aperture is modified to produce electric resistivity that is higher than the electrical resistivity within the bounds of the confining aperture. (As a result, in different embodiments at least one of the following conditions may be satisfied: a) a first portion of at least one of the first and second confining layers has a lower density of oxygen molecules than a second portion of the at least one of the first and second confining layers, and b) a first portion of at least one of the first and second confining layers has lower electrical resistivity than that of a second portion of the at least one of the first and second confining layers. Here, the first portion defines a confining aperture of the first and second confining apertures and the second portion is located outside of said confining aperture of the first and second confining apertures.)

FIGS. 9A, 9B, 9C, 9D, 9E, and 9F show examples of some of the possible patterns that could be used to define an asymmetric aperture.

The asymmetry of the metal contact layer in which such output aperture(s) are formed can, on one hand, affect the current injection profile during the operation of the device but can also be used to occlude parts of the are through which the light output is delivered that would otherwise normally be transparent to allow light emission in a regular non-patterned aperture situation.

For example, FIG. 9A shows a metal contact layer 902A that defines an output aperture 904A, where metal contact 902A has a wider transverse dimension on the right-hand side defining a partial occlusion that differentiates the opening 904A from a circular aperture opening of the same dimension, to prevent light emission at the region where the metal contact layer 902A overlaps and covers an aperture in the underlying confining layer of the device. As shown, the material layer of FIG. 9A includes a first portion dimensioned to define a closed upon itself stripe of material (shown as a substantially circular, annular stripe) and a second portion shaped as a segment of a circle (that is a part of a circle enclosed by the circle's periphery or edge and a line between two points on the periphery, also known as a chord). The first and second portions are in electrical and/or physical contact at at least one point (as shown—along a curved line).

The apertures in FIGS. 9B through 9D and 9F are defined by metal contact layer portions 906B, 906C, 906D and 906F (referred to as second portions of the metal contact layer) that are connected with metal contact layer portions 902B, 902C, 902D and 906F. (The later in turn, are referred to as first—and peripheral, at that—portions of the metal contact layer.) The material layers of FIGS. 9B, 9C, and 9D are dimensioned to include a first peripheral portion defining a ring-shaped stripe of material (as shown—a substantially circular ring of material) that has internal and external perimeters and closed upon itself, and a second portion formatted as a stripe of material extending along a radius of the first portion such as to cover a center of the first portion (in a specific case of the rotationally-symmetric first portion—such as to cover the center of rotational symmetry of the first portion). The material layers of FIGS. 9E, 9F are dimensioned to include a first peripheral portion defining a generally polygonally-shaped ring (as shown in this specific example—a rectangularly-shaped ring) having internal and external perimeters and closed upon itself, and a second portion shaped as a triangle sharing a boundary along its two sides with the first portion (in the case of FIG. 9E) or a stripe extending from the first portion inwardly (as shown in FIG. 9F—a stripe connecting two different sides of the first polygonal portion). Notably, in at least one of the embodiments of FIGS. 9B through 9D and 9F, the second portion of the peripheral material layer surrounds (that is, encloses) the second portion as seen in the plane of the first peripheral portion. Optionally, the second portion is appropriately dimensioned to cover the center of the area enclosed by the first peripheral portion (for example, in the case when the first portion has an axis of symmetry). The first and second portions are electrically and/or physically connected at at least one point.

Accordingly, in at least one embodiment of the VCSEL structure, the first peripheral portion (of the material layer that defines an output aperture of the VCSEL structure) may be dimensioned to define a ring-shaped stripe of material and the second portion of such material layer is dimensioned to satisfy one of the following conditions: (i) the second portion is configured as radially-extended stripe of material, and (ii) the second portion is configured as a stripe connecting two different sides of a polygonally-shaped first peripheral portion. At the same time, in at least one embodiment the second portion is configured to be electrically connected with the first peripheral portion at at least one point. Alternatively or in addition, in at least one embodiment of the VCSEL structure, the first peripheral portion (of the material layer that defines an output aperture of the VCSEL structure) may be dimensioned as a stripe of material having a closed polygonal perimeter, while the second portion is dimensioned to cover a surface area and establish electrical contact with at least one side of the polygonal perimeter.

It will be appreciated by a person of skill in the art, that the appropriate positioning and dimensioning of portions 906B, 906C, 906D and 906F is used to generally suppress light emission at those locations of the output surface of the laser structure where the metal contact layer is deposited, and, therefore, enforce the transverse mode formation to occur where the metal contact layer is not present. In specific examples of FIGS. 9B through 9D and 9F, for example, such configuration causes suppression of light emission at and/or about the geometrical center of the corresponding aperture and formation of spatial modes with ring-like shapes or “dumb-bell”-like shapes, each of which are known to be a higher-order transverse mode for a laser cavity having a circular cross-section. (The transverse mode of the output, generated in operation by an embodiment of the invention, that is described as having a dumb-bell shaped cross-sectional distribution of irradiance can be visualized, for example, as one having two lobes on either side with respect to the center of the distribution, which in turn carries substantially no light. Such transverse mode output is defined by either a single transverse mode or a combination of transverse modes. For the purposes of illustration only—and without any intent to limit the scope of this description—one can think of TEM01 or TEM10 or TEM(01) versions of laser modes as very specific examples of the cross-sectional, transverse distribution of irradiance in the laser output. The terms “ring-shaped transverse distribution of irradiance” or “ring-shaped transverse spatial mode”, on the other hand, refer to the distribution of irradiance that when detected is perceived as forming a ring—whether such distribution is formed with a single spatial mode or a combination of multiple spatial modes or filaments, for example as a result of superposition of multiple transverse modes each having a dumb-bell distribution of irradiance.) The resulting transverse modes can be characterized by at least one emission spot or area and with no emission spot located at the geometrical center of the output aperture. For example, during the operation of the VCSEL devices having output apertures of FIG. 9C and 9F, the output transverse modes are characterized by a light output in at least one of aperture regions 904C and 904C′, or a light output in at least one of aperture regions 904F and 904F′, respectively. For example, light formation may occur in both regions 904C and 904C′, producing two spatial regions of light output either side of metal 906C, thus are separated by a region of little or no light output, thus forming an output pattern with a dumbbell-like shape. The spatial mode pattern in these regions of the output aperture(s) can also be affected by the particular shape and any lateral offset of an aperture in the underlying confining layer within the VCSEL structure.

The ability to cause multimode spatial emission with suppressed emission at the center of an output aperture structure (effectively, at a longitudinal axis of a given VCSEL) can be useful in a variety of applications, including multimode optical fiber communication based on offset launch schemes, and in reducing speckle formation in operation of imaging systems.

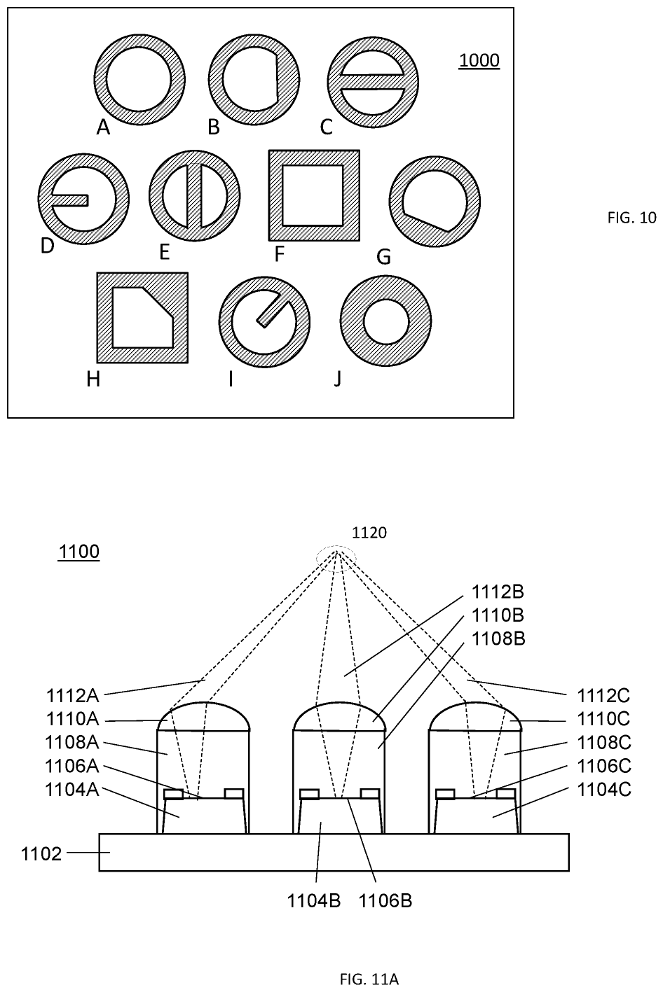

In a related embodiment, an array is formed of individual VCSELs having at least two different output-aperture shapes (for example—the shaped presented in FIGS. 9A-9F). An example 100 of such array, which includes a plurality of VCSEL devices capped with or having the output apertures labelled as A, B, C, D, E, F, G, H, I, and J (in this example—an array including ten constituent VCSELs) is illustrated in FIG. 10. The differently-shaped output apertures for the element devices in the VCSEL array 1000 causes a non-uniform spatial array of light output beams from the array 1000. Generally, in the so-configured VCSEL array, it is possible to have some of the constituent lasers with rotationally-symmetric output apertures and/or the laser in which the corresponding output aperture and the aperture in the confining layer are coaxial with one another, although it is intended that at least one of the output apertures of the constituent VCSEL devices i) remains non-coaxially-symmetric with the aperture in the corresponding confining layer and/or ii) has no more than two axes of symmetry. For example, constituent devices having output apertures A, F and J are shown having axially-symmetric apertures, whereas the output apertures C and E have only two axes of symmetry; the output apertures B, D, G, H and I have only one axis of symmetry, each. In a specific case, even if all of the constituent devices of the array employ the same shape of the output aperture, the spatial orientation of such output aperture can be judiciously chosen to differ from one constituent device to another so as to change the spatial output pattern of the individual constituent devices of the array with respect to each other.

Referring again to the example of the VCSEL array shown in FIG. 6, when apertures of the constituent VCSEL devices of the array are chosen to be shaped in a manner shown in FIG. 6, the metal layer defining the output aperture—such as the metal region shown in FIGS. 9A through 9F as 906B, 906C, 906D and 906F—can have a minimum feature size (for example, a width or a diameter) of 0.5 μm. The maximum feature size, such as a width or diameter, can be up to 25% (or up to 20%, or up to 10%, depending on the particular implementation) of the output aperture size. Another dimension of the metal regions of the output aperture(s) can extend across the cavity, for example, as shown in FIG. 9C and in FIG. 9F.

It therefore becomes clear to a person of ordinary skill in the art that with the use of embodiments of the invention illustrated in FIGS. 3 through 10 it is thus possible to form arrays of VCSELs that produce irregular output patterns of output light, regardless of whether the array itself has a regular spacing between the output apertures of the individual (constituent) lasers or not. Arrays of devices can produce complex output patterns that may be suited to achieve the goal of producing judiciously spatially-structured light generation.

Individual VCSEL devices and/or VCSEL arrays structured according to the idea of the present invention can further be integrated or operably-cooperated with auxiliary optical elements—such as microlenses or optical filters, for example example. In doing so, in some embodiments the microlenses may be structured to form a separate, stand-alone array of lens elements overlying (and combined with) the VCSEL array on the side producing light output. For example, microlenses may be fabricated on a separate transparent substrate that is attached and aligned to the overall laser array. In other embodiments, the microlenses may be formed on the backside of the surface of the substrate by using a number of different processes known to one of ordinary skill in the art. (One technique for forming such microlenses involves a photolithography process that defines a lens element with photoresist shaped as a cylinder or otherwise, which is then melted onto the substrate before having the lens shape transferred to the substrate through an etching process. The etch may be a Chlorine (Cl) based dry etch adjusted for or approaching an even etch selectivity between the substrate material and the photoresist, so as to etch both materials at close to or at the same rate. The photolithographic step used to create the lens elements is accomplished, for example, using a backside wafer alignment system common in the industry.

Regardless of whether the geometrical arrangement of the constituent VCSEL devices in a given VCSEL array is regular or irregular (and regardless of whether the array of corresponding output apertures is geometrically regular or irregular), the fact that at least some constituent VCSEL devices in the array are intentionally dimensioned to produce laser outputs with transverse distributions of irradiance that are asymmetric with respect to the centers of the corresponding output apertures causes the array of the output beams be, generally, irregularly spaced. As a result, when the array of the output apertures (of the VCSEL array) is aligned with the array of microlenses, the beams of light defined as the throughput of the array of microlenses can also be offset with respect to longitudinal axes of the constituent microlenses. Alternatively, even in the case when the output beams from the lasers of the VCSEL array are substantially-regularly spaced with respect to one another, the corresponding array of microlenses can be chosen to be geometrically irregular. Such variability affords the user to manipulate and modify the spatial distribution of the VCSEL array useful light output, based on a combination of the driving conditions of the chosen lasers and/or the chosen subsets of lasers within the VCSEL array that are driven such that the resulting, overall output beam from the VCSEL array equipped with the microlenses is focused and scanned over different spatial regions of interest.

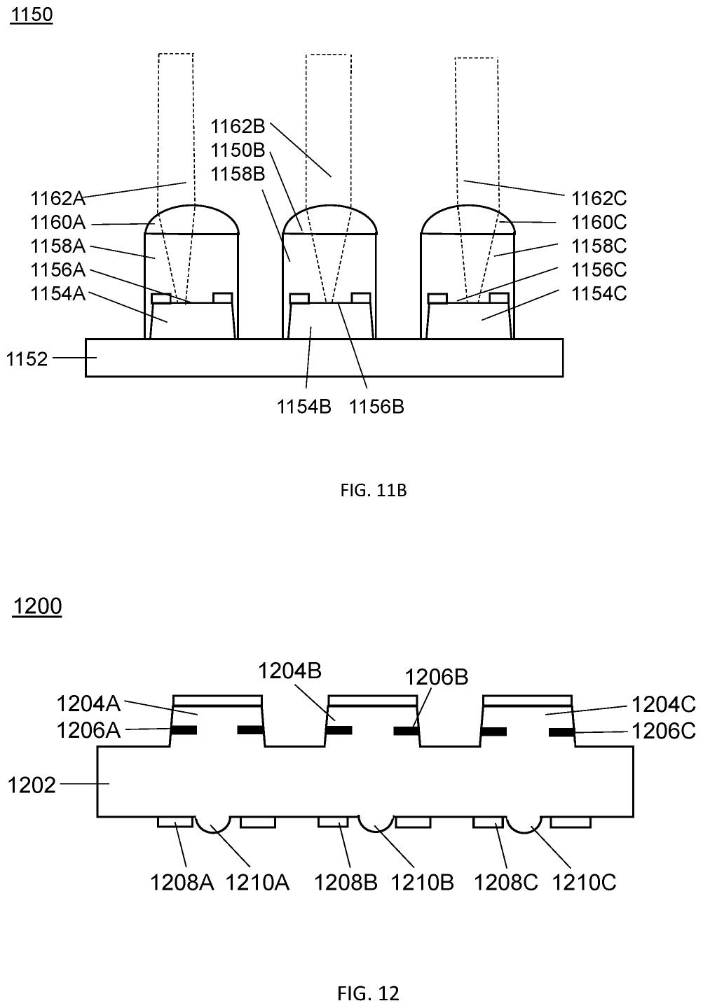

To this end, FIG. 11A shows a VCSEL array 1100 formed on a substrate 1102, integrated with a microlens array. In one implementation, microlenses 1110A, 1110B and 1110C of the microlens array may be individually integrated with the corresponding VCSEL devices 1104A, 1104B, and 1104C (which devices have apertures 1106A, 1106B and 1106C) with the use of a spacer or pedestal layer 1108A, 1108B and 1108C. Microlenses 1110A, 1110B and 1110C may be formed using any suitable optically transparent material (such as a polymer, for example), while the spacers or pedestals may be formed using either the same or different optically transparent material. In this example, the microlens array is aligned with the constituent output VCSEL-apertures, with no offset between each lenslet and the corresponding laser. The laser array 1100 is designed to shift at least some of the spatial modes in the constituent throughput beams off-center with respect to the centers of the corresponding output apertures and with respect to the central axes of the corresponding lens elements. As illustrated, the output beams of at least one laser of the array (as shown—the beams 1112A, 1112B and 1112C) can be deflected at an angle and focused or defocused, depending on the particular microlens design and spacing/separation distance from the corresponding lasing emitter. The microlenses do not have to be identical to one another. The dimensional flexibility allows the designer to converge the beams with a group of microlenses having different offsets with respect to the spatial distributions of irradiance generated by different laser devices. This control of the beam direction and (de)focusing facilitates, in one example, the use when all of the laser beams at the output from the microlenses are directed to the same area or a single spot (shown in FIG. 11A with a dashed line 1120), where an optical detector may be positioned to receive the optical signal. Numerous other focusing arrangements are possible, for example the one directed to illuminate a larger spot size, or to produce a collimated light output beam, or to produce an overall light beam with a desired degree of divergence. The integrated array may also be combined with additional optical elements to achieve other desired beam output characteristics. Other optical elements, such as diffusers or optical filters, for example, may be used in addition to or instead of the lenses.

To illustrate the possibility of achieving different output beam characteristics, FIG. 11B shows another VCSEL array 1150 formed on a substrate 1152 and integrated with a microlens array. Microlenses 1160A, 1160B and 1160C (shown as individual, stand-alone devices) may be integrated with the constituent VCSEL devices 1154A, 1154B, and 1154C that have corresponding output apertures 1156A, 1156B and 1156C. This integration is achieved—as illustrated in this example—with a respectively corresponding spacer or pedestal layer 1158A, 1158B, 1158C. The choice of materials for the spacer layer(s) and corresponding microlenses may be substantially the same as that discussed in reference to FIG. 11A. The microlenses or optical elements do not have to be geometrically identical. In this example, the constituent microlenses are aligned with the corresponding output apertures of the constituent VCSEL devices, with substantially no offset between each lens and the corresponding laser. The laser array 1150 is designed to spatially shift at least some of the spatial modes formed in operation of the laser devices off-center (with respect to the centers of the corresponding output apertures and with respect to the central axes of the corresponding microlenses). As illustrated, the beam of at least one laser device can be appropriately angularly deflected (as shown—beams 1162A, 1162B and 1162C) at an angle to produce different illumination spots on different regions of interest, or where different detectors are located.

FIG. 12 shows an example of a VCSEL array 1200 formed on a substrate 1202, and integrated with a microlens array formed on the back side of the microlens substrate 1202. As shown, the array of microlenses 1210A, 1210B and 1210C is integrated with the array of constituent VCSEL devices 1204A, 1204B, and 1204C that have corresponding confining apertures 1206A, 1206B and 1206C and as well as corresponding output apertures defined by metal contacts 1208A, 1208B and 1208C. Microlenses 1210A, 1210B and 1210C may be formed using any suitable known methods. In this example, the microlenses have different spatial alignments with respect to the corresponding apertures of the VCSEL devices. The central axes of the lenses of the array can be offset with respect to the axis of at least one of the two types of apertures in the case of at least some of the constituent VCSEL devices (that is, with respect to the axis of the output aperture and/or the axis of the confining aperture). In this example, the constituent lasers in the laser array are spaced regularly, while the immediately-adjacent-to-one-another microlenses are separated from one another with different distances (the distance between the lenses 1210A and 1210B, for example, is different from the distance between the lenses 1210B and 1210C). In a related implementation, VCSELs with irregular separations between the constituent laser devices may also be combined with an array in which the constituent microlenses are spaced regularly on the common substrate. According to the idea of the invention, similar arrangement(s) can also be applied to segmented arrays. The proposed flexibility of the operable cooperation between the array of microlenses and the array of VCSEL devices facilitates diversity in structuring the convergence of beams or other manipulation of beams originating from different segments of the laser array, as desired. While microlenses 1210A, 1210B and 1210C may be geometrically substantially identical, different designs may be used, and/or different optical elements may be used for each element 1210A, 1210B, and 1210C instead of or in addition to the lenses, such that the chosen optical elements of the array control the output beams from VCSEL devices and segments of arrays in different fashions. The resulting effect is the operation of the device 1200 and/or portions of this device to produce different light intensities and/or beam profiles.

To fabricate embodiments of semiconductor optoelectronic devices structured according to the idea of the invention, a plurality of layers can be deposited on an appropriate substrate in a first-materials-deposition chamber. The plurality of layers may include etch-stop layers; release layers (i.e., layers designed to release the semiconductor layers from the substrate when a specific process sequence, such as chemical etching, is applied); contact layers such as lateral conduction layers; buffer layers; layers forming reflectors or mirror structures, and/or or other semiconductor layers. For example, the sequence of layers deposited can include buffer layer(s), then a lateral conduction or contact layer(s), and then layer(s) forming a reflector of the VCSEL structure. Next, the substrate can be transferred to a second-materials-deposition chamber, where a cavity region and an active region are formed on top of the existing, already-deposited semiconductor layers. The substrate may then be transferred to either the first-materials-deposition chamber or to a third-materials-deposition chamber for deposition of additional mirror layer(s) and contact layers. Tunnel junctions may also be formed in some implementations.

The movement or repositioning/relocation of the substrate and semiconductor layers from one deposition chamber to another chamber is referred to as transfer. The transfer may be carried out in vacuum, at atmospheric pressure in air or another gaseous environment, or in an environment having mixed characteristics. The transfer may further be organized between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

For example, a dilute nitride active region and cavity region can be deposited in a first-materials-deposition chamber, while the AlGaAs/GaAs DBRs and other structural layers can be deposited in a second-materials-deposition chamber. To fabricate VCSEL devices discussed in this disclosure, some or all of the layers of a cavity region, including a dilute nitride based active region can be deposited with the use of molecular beam epitaxy (MBE) on one deposition chamber, and the remaining layers of the laser can be deposited with the use of chemical vapor deposition (CVD) in another materials deposition chamber.

In some embodiments, a surfactant, such as Sb or Bi, may be used when depositing any of the layers of the device. A small fraction of the surfactant may also incorporate within a layer.

A semiconductor device comprising a dilute nitride layer can be subjected to one or more thermal annealing treatments after growth. For example, a thermal annealing treatment includes the application of a temperature in a range from about 400° C. to about 1,000° C. for a duration between about 10 microseconds and about 10 hours. Thermal annealing may be performed in an atmosphere that includes air, nitrogen, arsenic, arsine, phosphorus, phosphine, hydrogen, forming gas, oxygen, helium, or any combination of the preceding materials.

The invention as recited in claims appended to this disclosure is intended to be assessed in light of the disclosure as a whole, including features disclosed in related art to which reference is made.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/- 20% of the value itself, preferably within the +/−10% range of the value itself, more preferably within the range of +/−5% of the value itself, and even more preferably within the range of +/−2% or less of the value itself. The term “substantially equivalent” may be used in the same fashion.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

Although specific embodiments have been illustrated and described herein, it will be appreciated by those of ordinary skill in the art that any arrangement that is devised to achieve the same purpose may be substituted for the specific embodiments shown. In a related embodiment, for example, a VCSEL structure is provided that has a longitudinal axis and that includes first and second reflectors; a gain medium between the first and second reflectors; and a peripheral material layer defining an output aperture therein (the output aperture dimensioned to have no more than two axes of symmetry of the output aperture; here, the peripheral material layer is a metallic layer configured as an electrical contact layer of the VCSEL structure, and the peripheral material layer is dimensioned to include a first peripheral portion and a second portion surrounded by the first peripheral portion). Such VCSEL structure may be configured to produce, in operation, a light output having a spatial distribution of intensity in one of the following forms: a) a ring-shaped distribution of intensity, and b) a dumb-bell-shaped distribution of intensity, as defined in a plane transverse to an axis of the light output, while an axis of the output aperture and an axis of the at least one internal aperture may be configured to not coincide with one another, and/or while a lateral extent of at least one of the peripheral material layer and the at least one confining material layer (in a first plane that is transverse to the longitudinal axis) may be chosen to be smaller than a lateral extent of the active region (in a second plane that is parallel to the first plane).

Overall, this application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiment of the above structures and fabrication methods are used. The scope of the embodiments of the present invention should be determined with reference to claims associated with these embodiments, along with the full scope of equivalents to which such claims are entitled.

1. A vertical cavity surface-emitting laser (VCSEL) structure having a longitudinal axis, the VCSEL structure comprising:
first and second reflectors;
a gain medium between the first and second reflectors;
a peripheral material layer defining an output aperture therein, and
at least one confining material layer disposed across the longitudinal axis between the first and second reflectors, the at least one confining material layer defining at least one confining aperture in the at least one confining material layer,
wherein a first axis and a second axis do not coincide with one another,
wherein the first axis is an axis of the output aperture and is transverse to a plane of the output aperture,
wherein the second axis is an axis of the at least one confining aperture and is transverse to a plane of the at least one confining aperture.

2. The VCSEL structure according to claim 1, wherein the VCSEL structure has only one axis of symmetry.

3. The VCSEL structure according to claim 1, wherein at least one of the following conditions is satisfied:
a) a value of a lateral offset, in a plane parallel to a plane of the at least one confining aperture, between the first axis and the second axis is at least 1 μm; or
b) the value of the lateral offset does not exceed 40% of a dimension of the at least one confining aperture.

4. The VCSEL structure according to claim 1, wherein at least one of the following conditions is satisfied:
a) the output aperture is dimensioned to have no more than two axes of symmetry of the output aperture in the plane of the output aperture;
b) wherein a lateral extent of at least one of the peripheral material layer and the at least one confining material layer, in a first plane is smaller than a lateral extent of an active region in a second plane, and wherein the first plane is transverse to the longitudinal axis and the second plane is parallel to the first plane; or
c) wherein the at least one confining layer includes first and second confining layers each of which is disposed between the first and second reflectors, and
wherein the first and second confining layers are located on the opposite sides of the gain medium.

5. The VCSEL structure according to claim 1,
wherein the peripheral material layer is a metallic layer configured as an electrical contact layer of the VCSEL structure, and
wherein the peripheral material layer is dimensioned to include a first peripheral portion and a second portion surrounded by the first peripheral portion.

6. The VCSEL structure according to claim 5,
wherein the first peripheral portion is dimensioned to define a ring-shaped stripe of material and the second portion is dimensioned to satisfy one of the following conditions:
(i) the second portion is configured as radially-extended stripe of material, and
(ii) the second portion is configured as a stripe connecting two different sides of a polygonally-shaped first peripheral portion; or
wherein the second portion is electrically connected at at least one point.

7. The VCSEL structure according to claim 1,
wherein the peripheral material layer is a metallic layer configured as an electrical contact layer of the VCSEL structure, and
wherein the peripheral material layer is dimensioned to include a first peripheral portion and a second portion surrounded by the first peripheral portion,
wherein the first peripheral portion is dimensioned to define a closed upon itself stripe of material having a closed internal perimeter and a closed external perimeter, and
wherein the second portion is dimensioned to cover a center of the first peripheral portion.

8. The VCSEL structure according to claim 1, configured to generate a light output having a spatial distribution of irradiance in one of the following forms:
a) a ring-shaped distribution of irradiance; or
b) a dumb-bell-shaped distribution of irradiance,
as defined in a plane transverse to an axis of the light output.

9. The VCSEL structure according to claim 1, wherein at least one of the following conditions is satisfied:
i) the at least one confining material layer includes first and second confining layers, the first confining layer having a first confining aperture therein and the second confining layer having a second confining aperture therein; or
ii) wherein the first and second confining layers are located on the opposite sides of the gain medium.

10. The VCSEL structure according to claim 9, wherein at least one of the following conditions is satisfied:
a) a first portion of at least one of the first and second confining layers has a density of oxygen molecules that is lower than that of a second portion of the at least one of the first and second confining layers; or
b) a first portion of at least one of the first and second confining layers has electrical resistivity that is lower than that of a second portion of the at least one of the first and second confining layers; and
wherein the first portion defines a chosen confining aperture, of the first and second confining apertures, and the second portion is located outside of the chosen confining aperture of the first and second confining apertures.

11. The VCSEL structure according to claim 9, wherein an axis of the first confining aperture and an axis of the second confining aperture do not coincide with one another such that there exists a non-zero lateral offset between projections of a center of the first confining aperture and a center of the second confining aperture on a plane substantially parallel to a plane of the at least one confining material layer.

12. The VCSEL structure according to claim 9,
wherein at least one of the first and second reflectors is a distributed Bragg reflector (DBR), and
wherein at least one of the first and second confining layers is disposed within bounds of the DBR.

13. A VCSEL array including a plurality of the VCSEL structures each configured according to claim 1.

14. The VCSEL array according to claim 13, wherein at least one of the following conditions is satisfied:
a) a first VCSEL structure from the plurality of the VCSEL structures is different from a second VCSEL structure from the plurality of the VCSEL structures;
b) each of at least first and second VCSEL structures from the plurality of the VCSEL structures has corresponding output and confining apertures that are not co-axial with one another;
c) a VCSEL structure from the plurality of the VCSEL structures has an output aperture that is rotationally-symmetric, and a confining aperture that is not co-axial with the output aperture of the VCSEL structure from the plurality of the VCSEL structures; or
d) at least two output apertures, respectively-corresponding to two VCSELs structures of the plurality of the VCSEL structures, have no more than two axes of symmetry each, wherein such axis of symmetry is defined in a plane of a corresponding aperture.

15. The VCSEL array according to claim 14, further comprising a plurality of lens elements respectively-corresponding to and operably cooperated with the plurality of the VCSEL structures,
wherein:
i) first and second locations, defined within bounds of the first and second output apertures of respectively-corresponding first and second VCSEL structures; or
ii) first and second axes of respectively-corresponding first and second lens elements from the plurality of lens elements are mutually shifted in a plane parallel to a layer of a VCSEL structure from the plurality of the VCSEL structures.

16. The VCSEL array according to claim 15, wherein at least one of the following conditions is satisfied:
a) longitudinal axes of constituent VCSEL structures of the array form a first spatially-irregular grid of axes; or
b) optical axes of lens elements from the plurality of lens elements form a second spatially-irregular grid of axes.

17. The VCSEL array according to claim 15, wherein the plurality of lens elements is formed on the same substrate and configured as a stand-alone optical component.

18. The VCSEL array according to claim 17, wherein the plurality of lens elements is separated from the plurality of the VCSEL structures by substrate.

19. The VCSEL structure according to claim 1, wherein a dimension of at least one of a) the output aperture or b) the at least one confining aperture is between 3 μm and 50 μm.

20. The VCSEL structure according to claim 5, wherein a minimum dimension of the second portion is at least 0.5 μm and smaller than 25% of the output aperture size.

21. The VCSEL structure according to claim 1, configured to generate light having a spectral bandwidth of a value that satisfies at least one of the following conditions:
i) the value is greater than 0.5 nm;
b) the value is greater than 1.0 nm; or
c) the value greater than 1.5 nm.

22-54. (canceled)
